(19) United States
(12) Patent Application Publication
(10) Pub. No.: US 2024/0357868 A1
(43) Pub. Date: Oct. 24, 2024

(54) DISPLAY PANEL AND DISPLAY APPARATUS

(71) Applicants: Chengdu BOE Optoelectronics Technology Co., Ltd., Sichuan Province (CN); BOE Technology Group Co., Ltd., Beijing (CN)

(72) Inventors: Ruqin ZHANG, Beijing (CN); Jinyu LI, Beijing (CN); Zhimeng SHAO, Beijing (CN); Yige QI, Beijing (CN); Pingchuan ZENG, Beijing (CN); Chao KONG, Beijing (CN); Gaokun HUANG, Beijing (CN)

(21) Appl. No.: 18/245,932

(22) PCT Filed: Jun. 29, 2022
(86) PCT No.: PCT/CN2022/102457

§ 371 Date: Mar. 20, 2023

(51) Int. Cl. H10K 59/122; H10K 59/35; H10K 59/80

(52) U.S. Cl. CPC H10K 59/122; H10K 59/352; H10K 59/879; H10K 59/8792

(57) ABSTRACT

Disclosed are a display panel and a display apparatus. The display panel includes: a base substrate, including a plurality of pixels; and a pixel defining layer, located on the base substrate and having a plurality of pixel openings; wherein the plurality of pixels are in one-to-one correspondence with the plurality of pixel openings; the plurality of pixels include first color pixels (spx1) and second color pixels (spx2); a decay rate of viewing angle brightness of pixel openings (KK1) of the first color pixels (spx1) in unit area is a first decay rate, a decay rate of viewing angle brightness of pixel openings (KK2) of the second color pixels (spx2) in unit area is a second decay rate.

The present application is a National Stage of International Application No. PCT/CN2022/102457, filed on Jun. 29, 2022, which is hereby incorporated by reference in its entirety.

### FIELD

The present disclosure relates to the technical field of display, in particular to a display panel and a display apparatus.

### BACKGROUND

An active matrix organic light emitting device (AMOLED), as a current type light emitting device, is increasingly applied to the field of high-performance display due to its characteristics of being low in power consumption, self-luminous, high in color saturation, fast in response, wide in viewing angle, capable of realizing flexibility and the like.

### SUMMARY

A display panel provided by an embodiment of the present disclosure includes: a base substrate, including a plurality of pixels; and a pixel defining layer, located on the base substrate and provided with a plurality of pixel openings, wherein the plurality of pixels are in one-to-one correspondence with the plurality of pixel openings, the plurality of pixels include first color pixels and second color pixels, a decay rate of viewing angle brightness of pixel openings of the first color pixels in unit area is a first decay rate, a decay rate of viewing angle brightness of pixel openings of the second color pixels in unit area is a second decay rate, and the first decay rate is smaller than the second decay rate; and an area of the pixel opening of one of the first color pixels is smaller than an area of the pixel opening of one of the second color pixels.

In some possible implementations, in a first direction, the pixel opening of one of the first color pixels is provided with a first size, the pixel opening of one of the second color pixels is provided with a second size, and the first size is smaller than the second size.

In some possible implementations, a ratio of the first size to the second size is in a range of 1:1.2˜1:1.6.

In some possible implementations, in a second direction, the pixel opening of one of the first color pixels is provided with a third size, the pixel opening of one of the second color pixels is provided with a fourth size, the third size is smaller than the fourth size, and the second direction intersects with the first direction.

In some possible implementations, a ratio of the third size to the fourth size is in a range of 1:1.2˜1:1.6.

In some possible implementations, the plurality of pixels further include third color pixels; and the area of the pixel opening of one of the second color pixels is smaller than an area of a pixel opening of one of the third color pixels.

In some possible implementations, the display panel further includes: a black matrix, located on a side of the pixel defining layer facing away from the base substrate, wherein the black matrix is provided with a plurality of black matrix openings, the plurality of black matrix openings are in one-to-one correspondence with the plurality of pixel openings; and orthographic projections of bottom ends of the black matrix openings on the base substrate cover orthographic projections of bottom ends of the corresponding pixel openings on the base substrate.

In some possible implementations, in the first color pixel, first opening spacing is between an edge of an orthographic projection of a bottom end of a black matrix opening on the base substrate and an edge of the orthographic projection of the bottom end of the pixel opening on the base substrate, in the second color pixel, second opening spacing is between an edge of an orthographic projection of a bottom end of a black matrix opening on the base substrate and an edge of the orthographic projection of the bottom end of the pixel opening on the base substrate; and the first opening spacing is smaller than the second opening spacing.

In some possible implementations, a ratio of the first opening spacing to the second opening spacing is a range of 1:1.2˜1:2.2.

In some possible implementations, the plurality of pixels further include the third color pixels, and in each of the third color pixels, third opening spacing is between an edge of an orthographic projection of a bottom end of a black matrix opening on the base substrate and an edge of the orthographic projection of the bottom end of the pixel opening on the base substrate; and the third opening spacing is not smaller than the first opening spacing and smaller than the second opening spacing.

In some possible implementations, the display panel further includes: a first refractive index layer, located on the side of the pixel defining layer facing away from the base substrate; and a second refractive index layer, located on a side of the first refractive index layer facing away from the base substrate; wherein a refractive index of the first refractive index layer is smaller than a refractive index of the second refractive index layer; the first refractive index layer is provided with adjusting structures, and each of the adjusting structures corresponds to at least one of the first color pixel and the second color pixel; and the adjusting structure is configured to reduce an emergent angle of light rays emitted from the pixel opening of the corresponding pixel.

In some possible implementations, the adjusting structure includes a groove, side walls of the groove are in a slope shape, and the second refractive index layer fills the groove; and the groove corresponds to the first color pixel, and an orthographic projection of a bottom end of the pixel opening of the first color pixel on the base substrate covers an orthographic projection of a bottom end of the groove on the base substrate.

In some possible implementations, a first indentation value is between an edge of the orthographic projection of the bottom end of the pixel opening of the first color pixel on the base substrate and an edge of the orthographic projection of the bottom end of the groove on the base substrate, and the first indentation value is not smaller than zero and not larger than 2 μm.

In some possible implementations, an orthographic projection of a top end of the pixel opening of the first color pixel on the base substrate covers an orthographic projection of a top end of the groove on the base substrate; or the orthographic projection of the top end of the pixel opening of the first color pixel on the base substrate is located within the orthographic projection of the top end of the groove on the base substrate.

In some possible implementations, the adjusting structure includes a concave lens array; the second refractive index layer fills the concave lens array; and the concave lens array corresponds to the second color pixel, and the orthographic projection of the bottom end of the pixel opening of the second color pixel on the base substrate covers an orthographic projection of a region where the concave lens array is located on the base substrate.

In some possible implementations, in the concave lens array, sizes of all the concave lenses are the same, and spacing distances between every two adjacent concave lenses are the same.

In some possible implementation, the plurality of pixels further include the third color pixels; one of the first color pixels, one of the second color pixels and one of the third color pixels constitute a repeating unit; in the repeating unit, the first color pixel and the second color pixel are arranged in the first direction, and a straight line passing through a center of the pixel opening of the third color pixel and perpendicular to the first direction is located at a gap between the pixel opening of the first color pixel and the pixel opening of the second color pixel; and a plurality of repeating units are arranged in sequence in the first direction and constitute pixel rows.

In some possible implementations, the plurality of pixels further include the third color pixels; one first color pixel, two second color pixels and one third color pixel constitute a repeating unit; in the repeating unit, centers of the pixel openings of the first color pixel, the two second color pixels and the third color pixel constitute a quadrangle, a connecting line of the center of the pixel opening of the first color pixel and the center of the pixel opening of the third color pixel constitutes a first diagonal line of the quadrangle, and the repeating units are arranged in sequence in a direction parallel to the first diagonal line and constitute pixel rows.

In some possible implementations, the first color pixels are red pixels, the second color pixels are green pixels, and the third color pixels are blue pixels.

In some possible implementations, an orthographic projection of the pixel opening of any one pixel in the plurality of pixels on the base substrate is in a shape of at least one of rectangle, rhombus or circle.

A display apparatus provided by an embodiment of the present disclosure includes the above display panel.

### BRIEF DESCRIPTION OF THE DRAWINGS

FIG. 1 is a diagram of some W viewing angle CIE chromatic coordinate trajectories when an OLED display panel generates white light by using the mixing of three-primary-color light of red, green and blue in the related art.

FIG. 2 is a diagram of some monochromatic viewing angle brightness decays of a red OLED, a green OLED and a blue OLED in the related art.

FIG. 3 is a schematic diagram of some contrasts of specific parameters of W viewing angle color cast and W viewing angle brightness decay ratios when an OLED display panel generates white light by using the mixing of three-primary-color light of red, green and blue in the related art.

FIG. 4 is a cross-sectional view of some structures of a display panel provided by an embodiment of the present disclosure.

FIG. 5 is a schematic diagram of a light path provided by an embodiment of the present disclosure.

FIG. 6 is a top view of some structures of a display panel provided by an embodiment of the present disclosure.

FIG. 7 is a top view of some other structures of a display panel provided by an embodiment of the present disclosure.

FIG. 8 is a cross-sectional view of yet some other structures of a display panel provided by an embodiment of the present disclosure.

FIG. 9A is a cross-sectional view of yet some other structures of a display panel provided by an embodiment of the present disclosure.

FIG. 9B is a cross-sectional view of yet some other structures of a display panel provided by an embodiment of the present disclosure.

FIG. 10A is a diagram of some W viewing angle CIE chromatic coordinate trajectories when a display panel generates white light by using the mixing of three-primary-color light of red, green and blue provided by an embodiment of the present disclosure.

FIG. 10B is a diagram of some monochromatic viewing angle brightness decays of a red pixel, a green pixel and a blue pixel provided by an embodiment of the present disclosure.

FIG. 10C is a schematic diagram of some contrasts of specific parameters of W viewing angle color cast and W viewing angle brightness decay ratios when a display panel generates white light by using the mixing of three-primary-color light of red, green and blue provided by an embodiment of the present disclosure.

FIG. 11 is a cross-sectional view of yet some other structures of a display panel provided by an embodiment of the present disclosure.

FIG. 12 is a cross-sectional view of yet some other structures of a display panel provided by an embodiment of the present disclosure.

FIG. 13 is a cross-sectional view of yet some other structures of a display panel provided by an embodiment of the present disclosure.

FIG. 14 is a cross-sectional view of yet some other structures of a display panel provided by an embodiment of the present disclosure.

FIG. 15 is a cross-sectional view of yet some other structures of a display panel provided by an embodiment of the present disclosure.

FIG. 16 is a cross-sectional view of yet some other structures of a display panel provided by an embodiment of the present disclosure.

FIG. 17A is a diagram of some other W viewing angle CIE chromatic coordinate trajectories when a display panel generates white light by using the mixing of three-primary-color light of red, green and blue in the related art.

FIG. 17B is a diagram of some other monochromatic viewing angle brightness decays of a red pixel, a green pixel and a blue pixel in the related art.

FIG. 17C is a schematic diagram of some other contrasts of specific parameters of W viewing angle color cast and W viewing angle brightness decay ratios when a display panel generates white light by using the mixing of three-primary-color light of red, green and blue in the related art.

FIG. 18A is a diagram of some other W viewing angle CIE chromatic coordinate trajectories when a display panel generates white light by using the mixing of three-primary-color light of red, green and blue provided by an embodiment of the present disclosure.

FIG. 18B is a diagram of some other monochromatic viewing angle brightness decays of a red pixel, a green pixel and a blue pixel provided by an embodiment of the present disclosure.

FIG. 18C is a schematic diagram of some other contrasts of specific parameters of W viewing angle color cast and W viewing angle brightness decay ratios when a display panel generates white light by using the mixing of three-primary-color light of red, green and blue provided by an embodiment of the present disclosure.

FIG. 19 is a cross-sectional view of yet some other structures of a display panel provided by an embodiment of the present disclosure.

FIG. 20 is a cross-sectional view of yet some other structures of a display panel provided by an embodiment of the present disclosure.

FIG. 21A is a diagram of yet some other W viewing angle CIE chromatic coordinate trajectories when a display panel generates white light by using the mixing of three-primary-color light of red, green and blue provided by an embodiment of the present disclosure.

FIG. 21B is a diagram of yet some other monochromatic viewing angle brightness decays of a red pixel, a green pixel and a blue pixel provided by an embodiment of the present disclosure.

FIG. 21C is a schematic diagram of yet some other contrasts of specific parameters of W viewing angle color cast and W viewing angle brightness decay ratios when a display panel generates white light by using the mixing of three-primary-color light of red, green and blue provided by an embodiment of the present disclosure.

FIG. 22 is a cross-sectional view of yet some other structures of a display panel provided by an embodiment of the present disclosure.

FIG. 23A is a diagram of yet some other W viewing angle CIE chromatic coordinate trajectories when a display panel generates white light by using the mixing of three-primary-color light of red, green and blue provided by an embodiment of the present disclosure.

FIG. 23B is a diagram of yet some other monochromatic viewing angle brightness decays of a red pixel, a green pixel and a blue pixel provided by an embodiment of the present disclosure.

FIG. 23C is a schematic diagram of yet some other contrasts of specific parameters of W viewing angle color cast and W viewing angle brightness decay ratios when a display panel generates white light by using the mixing of three-primary-color light of red, green and blue provided by an embodiment of the present disclosure.

### DETAILED DESCRIPTION OF THE EMBODIMENTS

In order to make objectives, technical solutions and advantages of embodiments of the present disclosure clearer, the technical solutions of the embodiments of the present disclosure will be clearly and fully described below with reference to the accompanying drawings of the embodiments of the present disclosure. Apparently, the described embodiments are only some, but not all of the embodiments of the present disclosure. The embodiments in the present disclosure and features in the embodiments may be mutually combined without conflicts. Based on the described embodiments of the present disclosure, all other embodiments obtained by those ordinarily skilled in the art without creative work fall within the protection scope of the present disclosure.

Unless otherwise defined, technical or scientific terms used in the present disclosure should be understood commonly by those ordinarily skilled in the art to which the present disclosure pertains. “First”. “second” and similar words used in the present disclosure do not denote any sequence, quantity or significance, but are only used for distinguishing different components. “Include” or “contain” or similar words mean that a component or an item preceding the word covers components or items listed after the word and their equivalents without excluding other components or items. “Connection”. “connected” and similar words may include electrical connection, direct or indirect, instead of being limited to physical or mechanical connection.

It needs to be noted that sizes and shapes of all figures in the accompanying drawings do not reflect a true scale and are only intended to illustrate contents of the present disclosure. The same or similar reference numbers denote the same or similar components or components with the same or similar functions all the time.

In general, in order to reduce reflectivity of an internal structure of an OLED display panel to ambient light, the following two manners are usually adopted. In a first manner, a circular polarizer is attached to a light-emitting side of the OLED display panel, and the circular polarizer can reduce an emergent quantity, from a light-emitting surface, of ambient light entering the OLED display panel after being reflected by the internal structure of the OLED display panel. In a second manner, a color photoresist layer and a black matrix, namely, a color filter on encapsulation (COE) structure and a black matrix, are arranged on an encapsulation layer of the OLED display panel, and as the color photoresist layer can play a role in filtering light rays, the emergent quantity, from the light-emitting surface, of the ambient light entering the OLED display panel after being reflected by the internal structure of the OLED display panel may be reduced as well. Besides, compared with the circular polarizer, the color photoresist layer has a higher transmittance for light rays emitted by the OLED display panel, and a thickness of the OLED display panel integrated with the color photoresist layer is lower, so it is the development trend that the OLED display panel adopts the COE structure and the black matrix.

However, in the OLED display panel integrated with the color photoresist layer, decay rates of light rays emitted by OLEDs in different colors at different viewing angles are inconsistent, which leads to a phenomenon of color cast during image display of the display panel at the different viewing angles. For example, when the OLED display panel displays a white image, a phenomenon of turning blue or pink and the like may occur. Accordingly, a display effect of the display panel is poor.

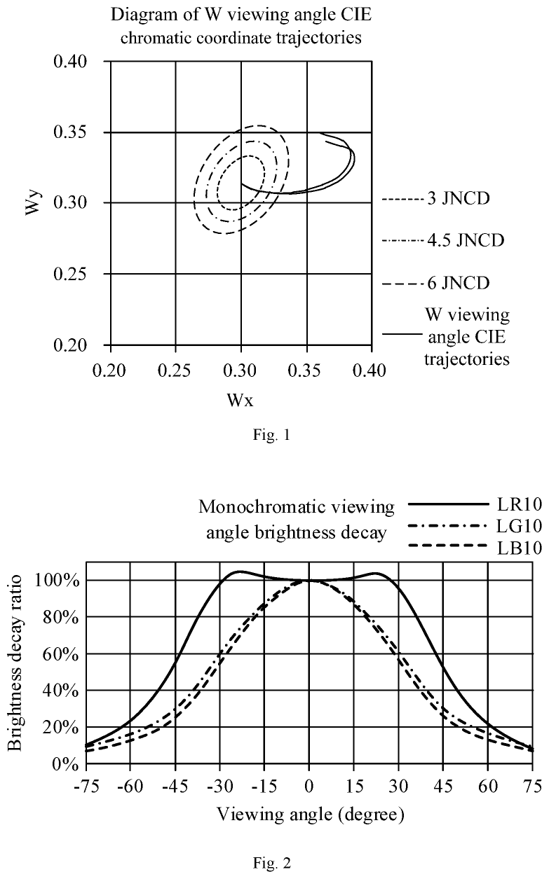

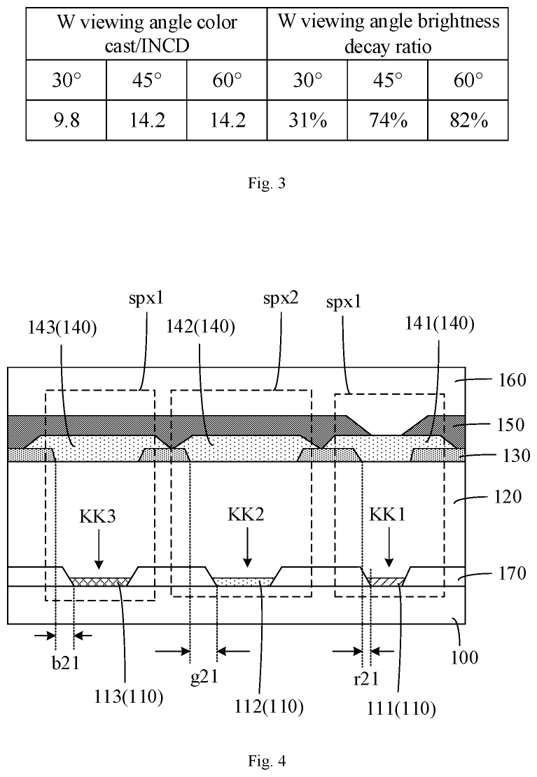

For example, the display panel may include a plurality of light-emitting devices in different colors. These light-emitting devices in different colors may include: red light-emitting devices emitting red light, green light-emitting devices emitting green light and blue light-emitting devices emitting blue light, so color mixture may be performed through three-primary-color light of red, green and blue so as to realize color display. In actual application, due to influence of microcavity structures of the light-emitting devices, brightness decay rates of the light-emitting devices in different colors at different viewing angles are inconsistent. Consequently, the phenomenon of color cast will occur when the display panel displays the white image at the different viewing angles. Specifically, as shown in FIG. 1 to FIG. 3. FIG. 1 is a diagram of W viewing angle CIE (Commission Internationale d'Eclairage) chromatic coordinate trajectories when a display panel generates white light by using the mixing of red, green and blue light-emitting devices based on three-primary-color light in the related art. FIG. 2 is a diagram of monochromatic viewing angle brightness decays of a red light-emitting device, a green light-emitting device and a blue light-emitting device in the related art. FIG. 3 is a schematic diagram of contrasts of specific parameters of W viewing angle color cast and W viewing angle brightness decay ratios when a display panel adopts red, green and blue light-emitting devices to generate white light based on the mixing of three-primary-color light in the related art. LR10 represents a curve of a monochromatic viewing angle brightness decay of a red light-emitting device. LG10 represents a curve of a monochromatic viewing angle brightness decay of a green light-emitting device. LB10 represents a curve of a monochromatic viewing angle brightness decay of a blue light-emitting device. It can be seen from FIG. 1 to FIG. 3 that brightness decay rates of the light-emitting devices in different colors at different viewing angles are inconsistent, wherein the brightness decay of the red light-emitting device is slow, the brightness decay of the green light-emitting device is fast, and when the red, green and blue light-emitting devices are used to generate the white light based on the mixing of the three-primary-color light, the phenomenon of color cast will occur at the different viewing angles when the display panel performs image display.

In view of this, the display panel provided by the embodiment of the present disclosure, as shown in FIG. 4 to FIG. 7, includes: a base substrate 100 and a pixel defining layer 170 located on the base substrate 100. The base substrate 100 includes a plurality of pixels (such as spx1 to spx3). The pixel defining layer 170 has a plurality of pixels pixel openings (such as KK1 to KK3). The plurality of pixels are in one-to-one correspondence with the plurality of pixel openings. In other words, one pixel includes one pixel opening. Besides, the plurality of pixels include first color pixels spx1 and second color pixel spx2. A decay rate of viewing angle brightness of pixel openings of the first color pixels spx1 in unit area is a first decay rate, a decay rate of viewing angle brightness of pixel openings of the second color pixels spx2 in unit area is a second decay rate, and the first decay rate is smaller than the second decay rate. An area of the pixel opening of one first color pixel spx1 is smaller than an area of the pixel opening of one second color pixel spx2. In other words, the decay rate of the viewing angle brightness of the first color pixels spx1 is improved on the basis of being originally slow, so that the decay rate of the viewing angle brightness of the first color pixels spx1 is improved. The decay rate of the viewing angle brightness of the second color pixels spx2 is reduced on the basis of being originally fast, so that the decay rate of the viewing angle brightness of the second color pixels spx2 is reduced, and thus a difference between the decay rates of the first color pixels spx1 and the second color pixels spx2 is reduced. In this way, the brightness decays at the pixel openings with different light-emitting colors may be approximately balanced, and the problem of W viewing angle color cast is relieved.

In some embodiments of the present disclosure, as shown in FIG. 4 to FIG. 7, the plurality of pixels further include third color pixels spx3. One first color pixel spx1, one second color pixel spx2 and one third color pixel spx3 constitute one repeating unit. In the repeating unit, the first color pixel spx1 and the second color pixel spx2 are arranged in a first direction F1, and a straight line passing through a center of a pixel opening of the third color pixel spx3 and perpendicular to the first direction F1 is located at a gap between the pixel opening of the first color pixel spx1 and the pixel opening of the second color pixel spx2. A plurality of repeating units are arranged in sequence in the first direction F1 and constitute pixel rows. The plurality of pixel rows are arranged in sequence in a second direction F2. For example, the first direction F1 intersects with the second direction F2. For example, the first direction F1 is perpendicular to the second direction F2. Optionally, the first direction F1 is a row direction of the pixels, and the second direction F2 is a column direction of the pixels.

In some embodiments of the present disclosure, a pixel circuit array layer is arranged between the base substrate and the pixel defining layer. The pixel circuit array layer includes a plurality of pixel circuits. Each pixel opening is provided with one light-emitting device. One pixel circuit and one light-emitting device are arranged in each pixel, wherein the pixel circuit is coupled with the light-emitting device, so that a drive current is input into an anode of the light-emitting device through the pixel circuit to drive the light-emitting device to emit light.

For example, the plurality of pixels arranged on the base substrate may include red pixels, green pixels and blue pixels, so that color mixture may be performed through red, green and blue to realize color display. Besides, one pixel includes one pixel opening, so each pixel opening emits light in a corresponding color. Specifically, the red light-emitting devices emitting red light are arranged in the pixel openings included in the red pixels, the green light-emitting devices emitting green light are arranged in the pixel openings included in the green pixels, and the blue light-emitting devices emitting blue light are arranged in the pixel openings included in the blue pixels. Optionally, the light-emitting devices may be at least one of OLEDs or quantum dot light emitting diodes (QLEDs).

For example, as shown in FIG. 4, the first color pixels spx1 may be the red pixels, so the red light-emitting devices are arranged in the first color pixels spx1. The second color pixels spx2 may be the green pixels, so the green light-emitting devices are arranged in the second color pixels spx2. The third color pixels spx3 may be the blue pixels, so the blue light-emitting devices are arranged in the third color pixels spx3. Certainly, in actual application, color display may also be implemented by adopting other colors, so the first color pixels spx1, the second color pixels spx2 and the third color pixels spx3 may also be pixels in other colors, moreover, which colors of pixels the first color pixels spx1, the second color pixels spx2 and the third color pixels spx3 are specifically may be determined according to demands of the actual application and is not limited here.

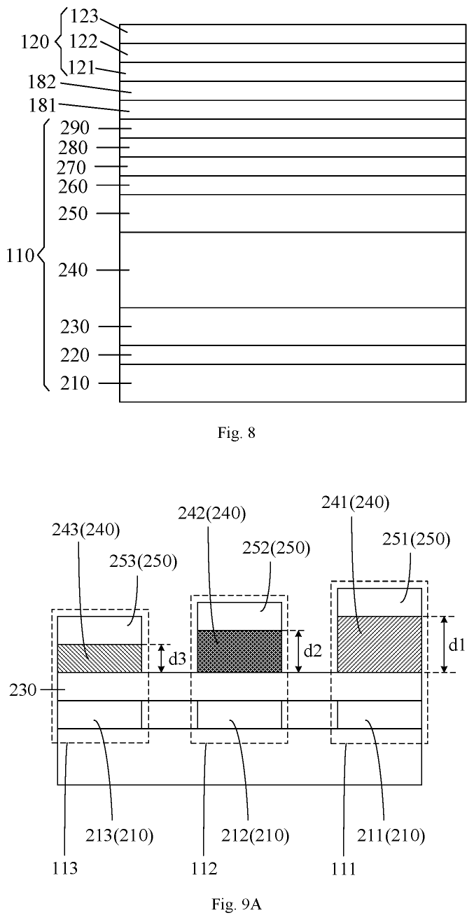

For example, as shown in FIG. 8, each light-emitting device may include an anode 210, a hole injection layer 220, a first hole transport layer 230, a second hole transport layer 240, a light-emitting layer 250, a hole blocking layer 260, an electron transport layer 270, an electron injection layer 280 and a cathode 290 which are arranged sequentially in stack. The hole injection layer 220, the first hole transport layer 230, an electron blocking layer, the hole blocking layer 260, the electron transport layer 270 and the electron injection layer 280 may further improve performance of the display panel. The present disclosure does not limit specific materials of the hole injection layer 220, the first hole transport layer 230, the electron blocking layer, the hole blocking layer 260, the electron transport layer 270 and the electron injection layer 280, and those skilled in the art may make selection and adjustment according to using demands, for example, a material of forming the electron injection layer 280 may be Yb.

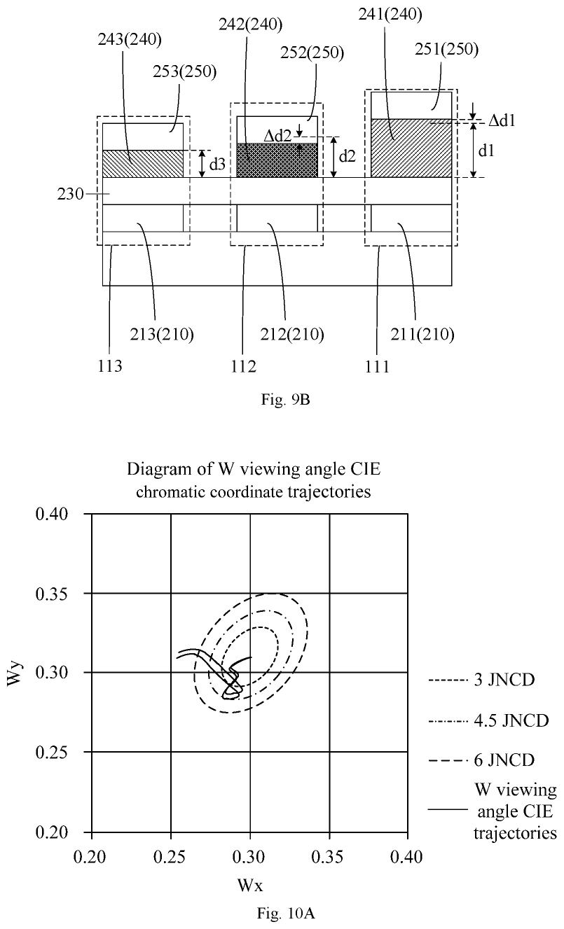

In some embodiments of the present disclosure, the second hole transport layer 240 includes a plurality of second hole transport sub-layers, and each light-emitting device includes one second hole transport sub-layer. The second hole transport sub-layers in the different light-emitting devices are independent of one another. For example, as shown in FIG. 9A, each red light-emitting device includes an anode 211, a second hole transport sub-layer 241 and a light-emitting layer 251, and the second hole transport sub-layer 241 is located between the first hole transport layer 230 and the light-emitting layer 251. Each green light-emitting device includes an anode 212, a second hole transport sub-layer 242 and a light-emitting layer 252, and the second hole transport sub-layer 242 is located between the first hole transport layer 230 and the light-emitting layer 252. Each blue light-emitting device includes an anode 213, a second hole transport sub-layer 243 and a light-emitting layer 253, and the second hole transport sub-layer 243 is located between the first hole transport layer 230 and the light-emitting layer 253. A thickness d1 of the second hole transport sub-layer 241 is greater than a thickness d2 of the second hole transport sub-layer 242 and greater than a thickness d3 of the second hole transport sub-layer 243. In this way, a cavity length of a microcavity of the red light-emitting device is greater than a cavity length of a microcavity of the green light-emitting device and greater than a cavity length of a microcavity of the blue light-emitting device, so that a realized color gamut may reach 115%@NTSC1931. Further, as shown in FIG. 9B, the thickness d1 may further be increased by Δd1 (for example, Δd1 may be 50˜70 Å), the thickness d2 is reduced by Δd2 (for example, Δd2 may be 70˜90 Å), and thus a realized color gamut may reach 125%@NTSC1931. It needs to be noted that though thicknesses of the second hole transport sub-layers 241˜243 are different, the thickness difference is very small relative to a thickness of a layered structure in the display panel and will not cause unevenness of film layers.

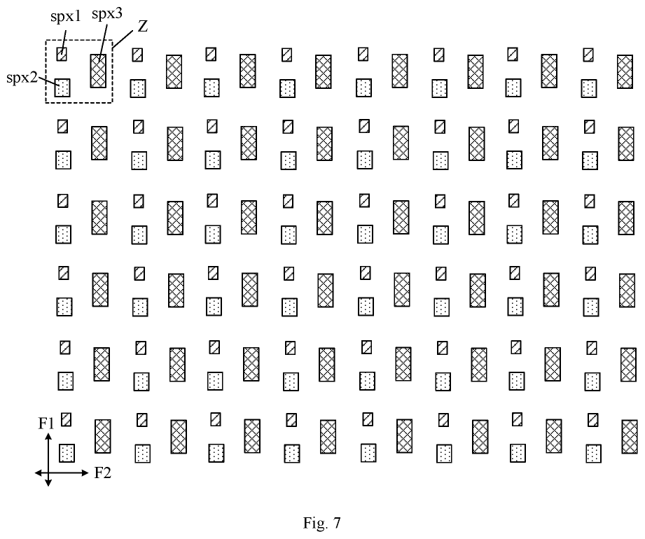

In some embodiments of the present disclosure, as shown in FIG. 6 and FIG. 7, an orthographic projection of the pixel opening of any one of the plurality of pixels on the base substrate 100 is rectangular. For example, an orthographic projection of the pixel opening KK1 of the first color pixel spx1 on the base substrate 100 is rectangular, an orthographic projection of the pixel opening KK2 of the second color pixel spx2 on the base substrate 100 is also rectangular, and an orthographic projection of the pixel opening KK3 of the third color pixel spx3 on the base substrate 100 is also rectangular. Besides, long edges of the pixel opening KK1 of the first color pixel spx1, long edges of the pixel opening KK2 of the second color pixel spx2 and long edges of the pixel opening KK3 of the third color pixel spx3 are all parallel to the first direction F1. Short edges of the pixel opening KK1 of the first color pixel spx1, short edges of the pixel opening KK2 of the second color pixel spx2 and short edges of the pixel opening KK3 of the third color pixel spx3 are all parallel to the second direction F2.

It needs to be noted that the above description is made by taking the orthographic projections of the pixel openings on the base substrate being rectangular as an example. The embodiment of the present disclosure does not limit shapes of the orthographic projections of the pixel openings on the base substrate. For example, the shapes of the orthographic projections of the pixel openings on the base substrate may also be a circle, an ellipse, or other regular or irregular polygons. Besides, shapes of the orthographic projections of the pixel openings of the pixels in the different colors on the base substrate may be the same or not (as long as at least part of edges meet the above ratio at the moment).

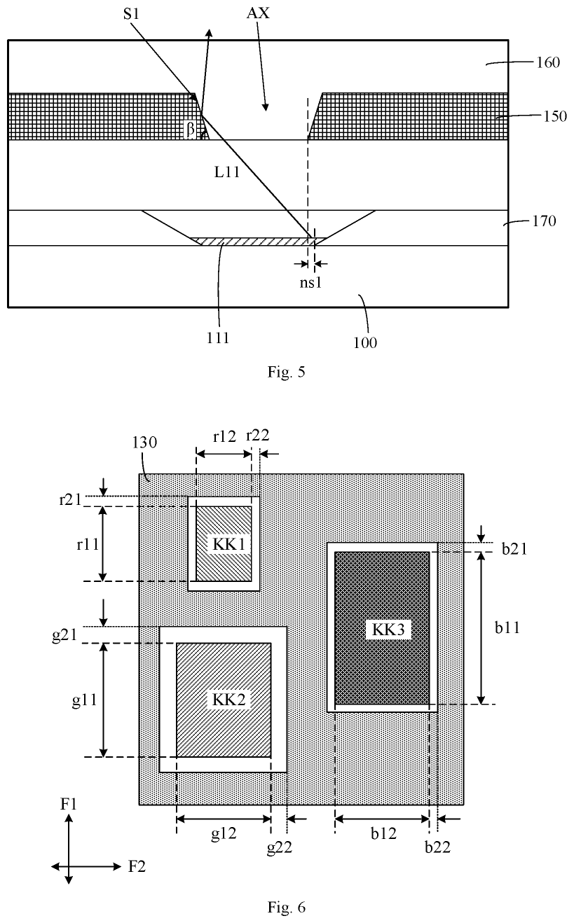

In some embodiments of the present disclosure, a section of each pixel opening may be an inverted trapezoid, and an area of the pixel opening of each pixel may be an area of an orthographic projection of a top end (namely, a long edge of the inverted trapezoid) of the pixel opening on the base substrate 100. For example, as shown in FIG. 4 and FIG. 5, an area of the pixel opening KK1 of the first color pixel spx1 is an area of an orthographic projection of a top end (namely, the long edge of the inverted trapezoid) of the pixel opening KK1 on the base substrate 100. An area of the pixel opening KK2 of the second color pixel spx2 is an area of an orthographic projection of a top end (namely, the long edge of the inverted trapezoid) of the pixel opening KK2 on the base substrate 100. An area of the pixel opening KK3 of the third color pixel spx3 is an area of an orthographic projection of a top end (namely, the long edge of the inverted trapezoid) of the pixel opening KK3 on the base substrate 100.

In some embodiments of the present disclosure, as shown in FIG. 4 to FIG. 7, in the first direction F1, the pixel opening KK1 of one first color pixel spx1 has a first size r11, the pixel opening KK2 of one second color pixel spx2 has a second size g11, and the first size r11 is smaller than the second size g11. For example, a ratio of the first size r11 to the second size g11 is in a range of 1:1.2˜1:1.6. In other words, r11:g11 is in a range of 1:1.2˜1:1.6. Optionally, r11:g11 may be 1:1.2, or r11:g11 may be 1:1.3, or r11:g11 may be 1:1.4, or r11:g11 may be 1:1.5, or r11:g11 may be 1:1.6. In actual application, a specific numerical value of r11:g11 may be determined according to demands of the actual application and is not limited here.

In some embodiments of the present disclosure, as shown in FIG. 4 to FIG. 7, in the second direction F2, the pixel opening KK1 of one first color pixel spx1 has a third size r12, the pixel opening KK2 of one second color pixel spx2 has a fourth size g12, and the third size r12 is smaller than the fourth size g12. For example, a ratio of the third size r12 to the fourth size g12 is in a range of 1:1.2˜1:1.6. In other words, r12:g12 is in a range of 1:1.2˜1:1.6. Optionally, r12:g12 may be 1:1.2, or r12:g12 may be 1:1.3, or r12:g12 may be 1:1.4, or r12:g12 may be 1:1.5, or r12:g12 may be 1:1.6. In actual application, a specific numerical value of r12:g12 may be determined according to demands of the actual application and is not limited here.

In some embodiments of the present disclosure, as shown in FIG. 4 to FIG. 7, the area of the pixel opening KK2 of one second color pixel spx2 is smaller than the area of the pixel opening KK3 of one third color pixel spx3. In some examples, in the first direction F1, the pixel opening KK3 of one third color pixel spx3 has a fifth size b11. The fifth size b11 is greater than the second size g11. For example, r11:g11:b11 is in a range of 1:1.2:1.7˜1:1.6:1.9. Optionally, r11:g11:b11 is one of 1:1.2:1.7, 1:1.2:1.8, 1:1.2:1.9, 1:1.3:1.7, 1:1.3:1.8, 1:1.6:1.7, 1:1.6:1.8 or 1:1.6:1.9. In actual application, a specific numerical value of r11:g11:b11 may be determined according to demands of the actual application and is not limited here.

In some embodiments of the present disclosure, as shown in FIG. 4 to FIG. 7, in the second direction F2, the pixel opening KK3 of one third color pixel spx3 has a sixth size b12. The sixth size b12 is greater than the fourth size g12. For example, r12:g12:b12 is in a range of 1:1.2:1.7˜1:1.6:1.9. Optionally, r12:g12:b12 is one of 1:1.2:1.7, 1:1.2:1.8, 1:1.2:1.9, 1:1.3:1.7, 1:1.3:1.8, 1:1.6:1.7, 1:1.6:1.8 or 1:1.6:1.9. In actual application, a specific numerical value of r12:g12:b12 may be determined according to demands of the actual application and is not limited here.

For example, the above various sizes in the first direction F1 may be sizes, in the first direction F1, of orthographic projections of bottom ends (namely, short edges of the inverted trapezoids) of the corresponding pixel openings on the base substrate 100, and the above various sizes in the second direction F2 may be sizes, in the second direction F2, of orthographic projections of bottom ends (namely, short edges of the inverted trapezoids) of the corresponding pixel openings on the base substrate 100. Specifically, the first size r11 may be a size, in the first direction F1, of an orthographic projection of a bottom end (namely, the short edge of the inverted trapezoid) of the pixel opening KK1 of the first color pixel spx1 on the base substrate 100, and the second size g11 is a size, in the first direction F1, of an orthographic projection of a bottom end (namely, the short edge of the inverted trapezoid) of the pixel opening KK2 of the second color pixel spx2 on the base substrate 100. The fifth size b11 may be a size, in the first direction F1, of an orthographic projection of a bottom end (namely, the short edge of the inverted trapezoid) of the pixel opening KK3 of the third color pixel spx3 on the base substrate 100. The third size r12 may be a size, in the second direction F2, of an orthographic projection of a bottom end (namely, the short edge of the inverted trapezoid) of the pixel opening KK1 of the first color pixel spx1 on the base substrate 100, and the fourth size g12 is a size, in the second direction F2, of an orthographic projection of a bottom end (namely, the short edge of the inverted trapezoid) of the pixel opening KK2 of the second color pixel spx2 on the base substrate 100. The sixth size b12 may be a size, in the second direction F2, of an orthographic projection of a bottom end (namely, the short edge of the inverted trapezoid) of the pixel opening KK3 of the third color pixel spx3 on the base substrate 100.

It needs to be noted that the first size to the sixth size may also be sizes at the same position from the bottom ends (namely, the short edges of the inverted trapezoids) to the top ends (namely, the long edges of the inverted trapezoids) of the above pixel openings, that is, the sizes at the same position from the bottom ends (namely, the short edges of the inverted trapezoids) to the top ends (namely, the long edges of the inverted trapezoids) of the above pixel openings may also be suitable for parameter setting of the embodiment of the present disclosure. For example, the first size to the sixth size may also be sizes at the positions of the top ends (namely, the long edges of the inverted trapezoids) of the above pixel openings, that is, the sizes of the top ends (namely, the long edges of the inverted trapezoids) of the above pixel openings may also be suitable for parameter setting of the embodiment of the present disclosure.

In some embodiments of the present disclosure, as shown in FIG. 4 and FIG. 5, the display panel further includes an encapsulation layer 120, a black matrix 130 and a color photoresist layer 140. The encapsulation layer 120 is located on a side of the pixel defining layer 170 facing away from the base substrate 100, the black matrix 130 is located on a side of the encapsulation layer 120 facing away from the base substrate 100, and the color photoresist layer 140 is located on a side of the black matrix 130 facing away from the base substrate 100. For example, as shown in FIG. 8, the encapsulation layer 120 may have a first inorganic encapsulation layer 121, an organic encapsulation layer 122 and a second inorganic encapsulation layer 123 arranged in stack. Optionally, an optical coupling layer 181 and an LiF film layer 182 are further arranged between the encapsulation layer 120 and the cathode. Besides, a refractive index of the optical coupling layer 181 is smaller than refractive indexes of the LiF film layer 182 and the first inorganic encapsulation layer 121, so that the optical coupling layer 181, the LiF film layer 182 and the first inorganic encapsulation layer 121 may form a combination of high-low-high refractive indexes to improve a light extraction rate.

It needs to be noted that the black matrix 130 and the color photoresist layer 140 may also be arranged between the first inorganic encapsulation layer 121 and the organic encapsulation layer 122. Or, the black matrix 130 and the color photoresist layer 140 may also be arranged between the organic encapsulation layer 122 and the second inorganic encapsulation layer 123. In actual application, specific positions of the black matrix 130 and the color photoresist layer 140 may be determined according to demands of the actual application, which is not limited here.

In some embodiments of the present disclosure, as shown in FIG. 4 and FIG. 5, the black matrix 130 has a plurality of black matrix openings, and the plurality of black matrix openings are in one-to-one correspondence with the plurality of pixel openings. An orthographic projection of the color photoresist layer 140 on the base substrate 100 covers orthographic projections of the plurality of black matrix openings on the base substrate 100. Optionally, the color photoresist layer 140 has a plurality of photoresist layers 140 in different colors, the black matrix openings corresponding to the red pixels are covered with a red photoresist layer 140, the black matrix openings corresponding to the green pixels are covered with a green photoresist layer 140, and the black matrix openings corresponding to the blue pixels are covered with a blue photoresist layer 140.

In some embodiments of the present disclosure, as shown in FIG. 4, in each pixel, a section of the black matrix opening may also be an approximate inverted trapezoid, and an orthographic projection of a bottom end (namely, a short edge of the inverted trapezoid) of the black matrix opening on the base substrate 100 covers an orthographic projection of the bottom end (namely, the short edge of the inverted trapezoid) of the corresponding pixel opening on the base substrate 100. In this way, perpendicular to a plane where the base substrate 100 is located, the black matrix openings may expose the corresponding pixel openings as much as possible. It needs to be noted that in an actual process, a material of the black matrix is an organic material, and as the organic material has certain fluidity, the section of the actually fabricated black matrix cannot be in a shape of a complete inverted trapezoid, but in a shape similar to the inverted trapezoid. For example, within a process fluctuation range, the section of the actually fabricated black matrix is the inverted trapezoid of which the corners are circular arc.

In some embodiments of the present disclosure, in each first color pixel spx1, first opening spacing exists between an edge of an orthographic projection of a bottom end of a black matrix opening on the base substrate 100 and an edge of the orthographic projection of the bottom end of the pixel opening KK1 on the base substrate 100. In each second color pixel spx2, second opening spacing exists between an edge of an orthographic projection of a bottom end of a black matrix opening on the base substrate 100 and an edge of the orthographic projection of the bottom end of the pixel opening KK2 on the base substrate 100. The first opening spacing is smaller than the second opening spacing. For example, a ratio of the first opening spacing to the second opening spacing is in a range of 1:1.2˜1:2.2. Optionally, the range of the ratio of the first opening spacing to the second opening spacing is one of 1:1.2, 1:1.5, 1:1.8, 1:2.0 or 1:2.2. In actual application, a specific numerical value of the ratio of the first opening spacing to the second opening spacing may be determined according to demands of the actual application, which is not limited here.

For example, as shown in FIG. 4 and FIG. 6, in each first color pixel spx1, in the first direction F1, the first opening spacing r21 is between the edge of the orthographic projection of the bottom end of the black matrix opening on the base substrate 100 and the edge of the orthographic projection of the bottom end of the pixel opening KK1 on the base substrate 100. In each second color pixel spx2, in the first direction F1, the second opening spacing g21 exists between the edge of the orthographic projection of the bottom end of the black matrix opening on the base substrate 100 and the edge of the orthographic projection of the bottom end of the pixel opening KK2 on the base substrate 100. The first opening spacing r21 is smaller than the second opening spacing g21. For example, r21:g21 is in a range of 1:1.2˜1:2.2. Optionally, r21:g21 is one of 1:1.2, 1:1.5, 1:1.8, 1:2.0 or 1:2.2. In actual application, a specific numerical value of r21:g21 may be determined according to demands of the actual application, which is not limited here.

For example, as shown in FIG. 4 and FIG. 6, in each first color pixel spx1, in the second direction F2, the first opening spacing r22 exists between the edge of the orthographic projection of the bottom end of the black matrix opening on the base substrate 100 and the edge of the orthographic projection of the bottom end of the pixel opening KK1 on the base substrate 100. In each second color pixel spx2, in the second direction F2, the second opening spacing g22 exists between the edge of the orthographic projection of the bottom end of the black matrix opening on the base substrate 100 and the edge of the orthographic projection of the bottom end of the pixel opening KK2 on the base substrate 100. The first opening spacing r22 is smaller than the second opening spacing 922. For example, r22:g22 is in a range of 1:1.2˜1:2.2. Optionally, r22:g22 is one of 1:1.2, 1:1.5, 1:1.8, 1:2.0 or 1:2.2. In actual application, a specific numerical value of r22:g22 may be determined according to demands of the actual application, which is not limited here.

Further, as shown in FIG. 4 and FIG. 6, in each third color pixel spx3, third opening spacing exists between edges of an orthographic projection of a bottom end of a black matrix opening on the base substrate 100 and edges of the orthographic projection of the bottom end of the pixel opening on the base substrate 100. The third opening spacing is not smaller than the first opening spacing and is smaller than the second opening spacing. For example, a ratio of the first opening spacing to the third opening spacing is in a range of 1:1˜1:1.2. Optionally, a ratio of the first opening spacing to the second opening spacing to the third opening spacing is in a range of 1:1:1.2˜1:1.2:2.2. Optionally, the ratio of the first opening spacing to the second opening spacing to the third opening spacing is one of 1:1:1.2, 1:1:1.5, 1:1.2:1.8, 1:1.2:2.0 or 1:1.2:2.2. In actual application, a specific numerical value of the ratio of the first opening spacing to the second opening spacing to the third opening spacing may be determined according to demands of the actual application, which is not limited here.

For example, as shown in FIG. 4 and FIG. 6, in each third color pixel spx3, in the first direction F1, the third opening spacing b21 exists between the edge of the orthographic projection of the bottom end of the black matrix opening on the base substrate 100 and the edge of the orthographic projection of the bottom end of the pixel opening KK3 on the base substrate 100. The third opening spacing b21 is not smaller than the first opening spacing r21 and smaller than the second opening spacing g21. For example, r21:b21 is in a range of 1:1˜1:1.2. Optionally, r21:b21 is one of 1:1, 1:1.1 or 1:1.2. Further, r21:g21:b21 is 1:1:1.2˜1:1.2:2.2. In actual application, a specific numerical value of r21:b21 may be determined according to demands of the actual application, which is not limited here.

For example, as shown in FIG. 4 and FIG. 5, in each third color pixel spx3, in the second direction F2, the third opening spacing b22 exists between the edge of the orthographic projection of the bottom end of the black matrix opening on the base substrate 100 and the edge of the orthographic projection of the bottom end of the pixel opening KK3 on the base substrate 100. The third opening spacing b22 is not smaller than the first opening spacing r22 and is smaller than the second opening spacing g22. For example, r22:b22 is in a range of 1:1˜1:1.2. Optionally, r22:b22 is one of 1:1, 1:1.1 or 1:1.2. Further, r22:g22:b22 is 1:1:1.2˜1:1.2:2.2. In actual application, a specific numerical value of r22:b22 may be determined according to demands of the actual application, which is not limited here.

Optionally, the first opening spacing r21 and the first opening spacing r22 may be arranged to be the same. In this way, in each first color pixel spx1, the spacing between the edges of the orthographic projection of the bottom end of the black matrix opening on the base substrate 100 and the edges of the orthographic projection of the bottom end of the pixel opening KK1 on the base substrate 100 may be arranged uniformly, and arrangement uniformity of the pixel opening is improved.

Optionally, the second opening spacing g21 and the second opening spacing 922 may be arranged to be the same. In this way, in each second color pixel spx2, the spacing between the edges of the orthographic projection of the bottom end of the black matrix opening on the base substrate 100 and the edges of the orthographic projection of the bottom end of the pixel opening KK2 on the base substrate 100 may be arranged uniformly, and arrangement uniformity of the pixel opening is improved.

Optionally, the third opening spacing b21 and the third opening spacing b22 may be arranged to be the same. In this way, in each third color pixel spx3, the spacing between the edges of the orthographic projection of the bottom end of the black matrix opening on the base substrate 100 and the edges of the bottom end of the pixel opening KK3 on the base substrate 100 are arranged uniformly, and arrangement uniformity of the pixel opening is improved.

In the embodiment of the present application, as shown in FIG. 4 and FIG. 5, the display panel further includes: a first refractive index layer 150 and a second refractive index layer 160. The first refractive index layer 150 is located on the side of the pixel defining layer 170 facing away from the base substrate 100, and the second refractive index layer 160 is located on a side of the first refractive index layer 150 facing away from the base substrate 100. Besides, refractive indexes of the first refractive index layer 150 and the second refractive index layer 160 are different. For example, the refractive index of the first refractive index layer 150 is smaller than the refractive index of the second refractive index layer 160. Besides, the first refractive index layer 150 is provided with adjusting structures, and the adjusting structure corresponds to the first color pixel spx1. The adjusting structure is configured to reduce an emergent angle of light rays emitted from the pixel opening of the first color pixel spx1, so that the emergent angle of the light rays emitted from the pixel opening of the first color pixel spx1 and then emitted from the display panel is reduced. In this way, through the adjusting structure, a part of light rays emitted from the pixel opening of the first color pixel spx1 may be absorbed by the black matrix 130, so that a brightness decay rate of light beams emitted from the pixel opening of the first color pixel spx1 at a large viewing angle is reduced, a viewing angle brightness decay rate of the light rays emitted from the pixel opening of the first color pixel spx1 and a viewing angle brightness decay rate of light rays emitted from the pixel opening of the second color pixel spx2 keep consistent as much as possible, and thus color cast of the display panel may be reduced.

For example, as shown in FIG. 4 and FIG. 5, the adjusting structure may include a groove AX, side walls of the groove AX are in a slope shape, and the second refractive index layer 160 fills the groove AX. The groove AX corresponds to the first color pixel spx1, and the orthographic projection of the bottom end of the pixel opening of the first color pixel spx1 on the base substrate 100 covers an orthographic projection of a bottom end of the groove AX on the base substrate 100. For example, a section of each groove AX is an inverted trapezoid, the bottom end of the groove AX is a short edge of the inverted trapezoid, and a top end of the groove AX is a long edge of the inverted trapezoid. The section of each groove AX is the inverted trapezoid, the side wall of the groove AX is in the slope shape, and the refractive index of the second refractive index layer 160 is greater than the refractive index of the first refractive index layer 150, by designing a specific numerical value of an inclination angle β of the side wall of the groove AX, a total reflection plane may be formed on the side wall of the groove AX, and when light L11 emitted from an edge (such as a right side edge) of the pixel opening of the first color pixel spx1 is incident on a side wall position SI on a left side of the groove AX, total reflection may occur. Likewise, when light emitted from a left side edge of the pixel opening of the first color pixel spx1 is incident on a side wall position on a right side of the groove AX, total reflection may occur as well. In this way, light emitted from the pixel opening of the first color pixel spx1 can be converged to a front viewing angle to be emitted, the brightness decay rate of the light beams emitted from the pixel opening of the first color pixel spx1 at the large viewing angle may be increased, the viewing angle brightness decay rate of the light rays emitted from the pixel opening of the first color pixel spx1 and the viewing angle brightness decay rate of the light rays emitted from the pixel opening of the second color pixel spx2 keep consistent as much as possible, and thus color cast of the display panel may be reduced.

For example, as shown in FIG. 7, a first indentation value ns1 exists between the edge of the orthographic projection of the bottom end of the pixel opening of the first color pixel spx1 on the base substrate 100 and an edge of the orthographic projection of the bottom end of the groove AX on the base substrate 100, and the first indentation value ns1 is not smaller than zero and not larger than 2 μm, that is. 0≤ns1≤2 μm. In this way, when the light L11 emitted from the edges (such as the right side edges) of the pixel openings of the first color pixels spx1 is incident on the side wall positions SI on the left sides of the grooves AX, total reflection may occur. Optionally, ns1=0, the edges of the orthographic projections of the bottom ends of the pixel openings of the first color pixels spx1 on the base substrate 100 overlap the edges of the orthographic projections of the bottom ends of the grooves AX on the base substrate 100. Or, 0≤ns1≤2 μm, the edges of the orthographic projections of the bottom ends of the pixel openings of the first color pixels spx1 on the base substrate 100 do not overlap the edges of the orthographic projections of the bottom ends of the grooves AX on the base substrate 100, and the edges of the orthographic projections of the bottom ends of the grooves AX on the base substrate 100 are indented into the edges of the orthographic projections of the bottom ends of the pixel openings of the first color pixels spx1 on the base substrate 100. In this way, it can further make total reflection occur when the light L11 emitted from the edges (such as the right side edges) of the pixel openings of the first color pixels spx1 is incident on the side wall positions SI on the left sides of the grooves AX. Optionally, ns1 is one of 0.5 μm, 1.0 μm, 1.5 μm or 2 μm. In actual application, a specific numerical value of ns1 may be determined according to an environment of the actual application, which is not limited here.

For example, as shown in FIG. 4 and FIG. 5, an orthographic projection of the top end of the pixel opening KK1 of the first color pixel spx1 on the base substrate 100 covers an orthographic projection of a top end of the groove AX on the base substrate 100. In this way, it can further make total reflection occur when the light L11 emitted from the edge (such as the right side edge) of the pixel opening KK1 of the first color pixel spx1 is incident on the side wall position SI on the left side of the groove AX. Certainly, the orthographic projection of the top end of the pixel opening of the first color pixel on the base substrate may also be located within the orthographic projection of the top end of the groove on the base substrate, which is not limited here.

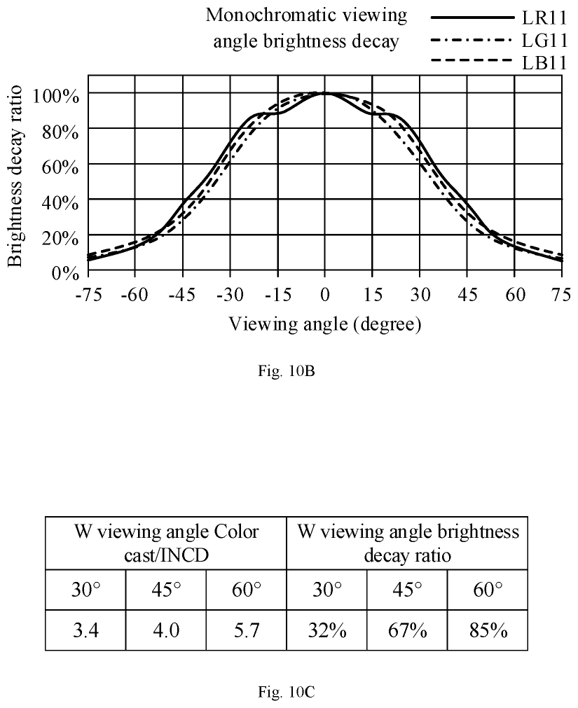

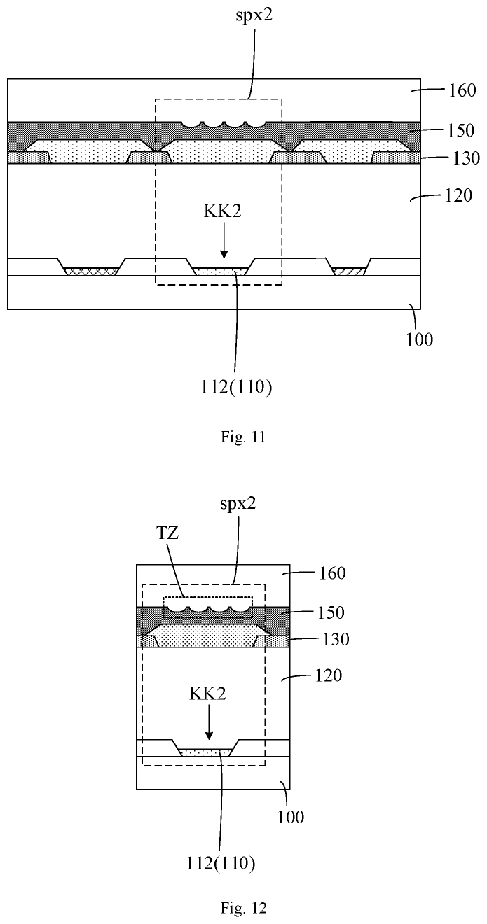

As shown in FIG. 10A to FIG. 10B. FIG. 10A is a diagram of W viewing angle CIE (Commission Internationale d′Eclairage) chromatic coordinate trajectories when a display panel shown in FIG. 4 generates white light by mixing of three-primary-color light of red, green and blue. FIG. 10B is a diagram of monochromatic viewing angle brightness decays of a display panel shown in FIG. 4. FIG. 10C is a schematic diagram of contrasts of specific parameters of W viewing angle color cast and W viewing angle brightness decay ratios when a display panel shown in FIG. 4 generates white light by mixing of three-primary-color light of red, green and blue. In FIG. 10B. LR11 represents a curve of a monochromatic viewing angle brightness decay of a red pixel. LG11 represents a curve of a monochromatic viewing angle brightness decay of a green pixel, and LB11 represents a curve of a monochromatic viewing angle brightness decay of a blue pixel. It can be seen from FIG. 10A to FIG. 10B that by using the display panel provided by the embodiment of the present disclosure, brightness decay rates of OLEDs in different colors at the different viewing angles tend to be consistent, and when RGB are mixed to generate the white light, color cast generated at the different viewing angles when the display panel performs image display is relieved.

An embodiment of the present disclosure provides a schematic structural diagram of some other display panels, as shown in FIG. 11. A transformation is made specific to the implementation in the above embodiment. Only a difference between the embodiment and the above embodiment is described below; and the same parts between them are omitted here.

In some embodiments of the present disclosure, as shown in FIG. 11 and FIG. 12, the adjusting structure may also include a concave lens array TZ; the second refractive index layer 160 fills the concave lens array TZ. The concave lens array TZ corresponds to the second color pixel spx2, the orthographic projection of the bottom end of the pixel opening KK2 of the second color pixel spx2 on the base substrate 100 covers an orthographic projection of a region where the concave lens array TZ is located on the base substrate 100. The refractive index of the second refractive index layer 160 is greater than the refractive index of the first refractive index layer 150, when light emitted from the pixel opening KK2 of the second color pixel spx2 is incident on the concave lens arrays TZ, the light enters an optically denser medium from an optically thinner medium, according to a normal of a center of a sphere of each concave lens, a direction of the light rays changes, the brightness decay rate of the light beams emitted from the pixel opening of the second color pixel spx2 at the large viewing angle may be reduced, the viewing angle brightness decay rate of the light rays emitted from the pixel opening KK1 of the first color pixel spx1 and the viewing angle brightness decay rate of the light rays emitted from the pixel opening KK2 of the second color pixel spx2 keep consistent as much as possible, and thus color cast of the display panel may be reduced.

In some embodiments of the present disclosure, as shown in FIG. 11 and FIG. 12, in the concave lens array TZ, sizes of all the concave lenses are the same. For example, an orthographic projection of each concave lens in the concave lens arrays TZ on the base substrate 100 is circular, and a size of each concave lens may be a diameter of the circular orthographic projection. In other words, the diameters of the orthographic projections of all the concave lenses in the concave lens array TZ on the base substrate 100 are the same.

In some embodiments of the present disclosure, as shown in FIG. 8 and FIG. 12, in the concave lens arrays TZ, spacing distances between every two adjacent concave lenses are the same. For example, distances between circle centers of the orthographic projections of every two adjacent concave lenses in the concave lens arrays TZ on the base substrate 100 are the same.

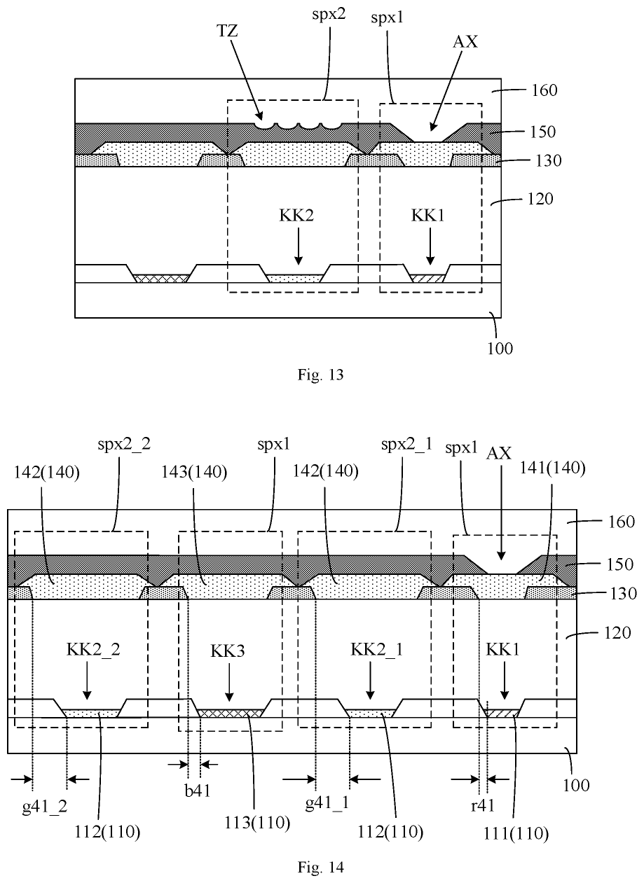

An embodiment of the present disclosure provides a schematic structural diagram of yet some other display panels, as shown in FIG. 13. A transformation is made specific to the implementation in the above embodiment. Only a difference between the embodiment and the above embodiment is described below; and the same parts between them are omitted here.

In some embodiments of the present disclosure, as shown in FIG. 13, the adjusting structure may not only include the groove AX but also include the concave lens array TZ. The groove AX corresponds to the first color pixel spx1, and the concave lens array TZ corresponds to the second color pixel spx2. It needs to be noted that implementations of the groove AX and the concave lens array TZ may refer to the above implementations and are omitted here.

In the embodiment of the present disclosure, by combining the two manners of the grooves AX and the concave lens arrays TZ, the viewing angle brightness decay rate of the light ray's emitted from the pixel opening of the first color pixel spx1 and the viewing angle brightness decay rate of the light rays emitted from the pixel opening of the second color pixel spx2 may keep consistent as much as possible, and thus color cast of the display panel may be reduced.

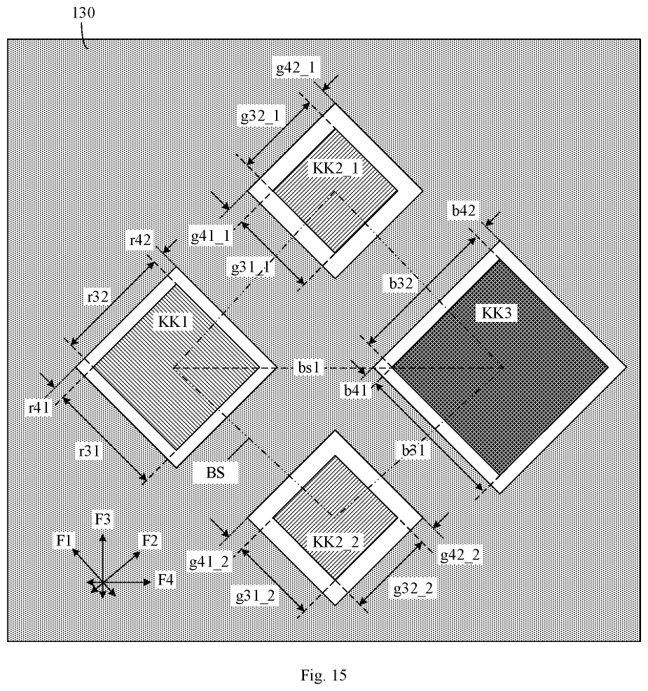

An embodiment of the present disclosure provides a schematic structural diagram of yet some other display panels, as shown in FIG. 14. A transformation is made specific to the implementation in the above embodiment. Only a difference between the embodiment and the above embodiment is described below; and the same parts between them are omitted here.

In some embodiments of the present disclosure, as shown in FIG. 14 to FIG. 16, one first color pixel spx1, two second color pixels spx2_1 and spx2_2 and one third color pixel spx3 constitute one repeating unit. In the repeating unit, centers of the pixel openings of the first color pixel spx1, the two second color pixels spx2_1 and spx2_2 and the third color pixel spx3 constitute a quadrangle BS, a connecting line of the center of the pixel opening of the first color pixel spx1 and the center of the pixel opening of the third color pixel spx3 constitute a first diagonal line bs1 of the quadrangle BS, and a connecting line of the centers of the pixel openings of the two second color pixels spx2_1 and spx2_2 constitute a second diagonal line of the quadrangle. Repeating units are arranged in sequence in a direction (namely, a fourth direction F4) parallel to the first diagonal line bs1 and constitute pixel rows. The plurality of pixel rows are arranged in sequence in a direction (namely, a third direction F3) perpendicular to the first diagonal line. For example, the third direction F3 is a column direction of the pixels, and the fourth direction F4 is a row direction of the pixels.

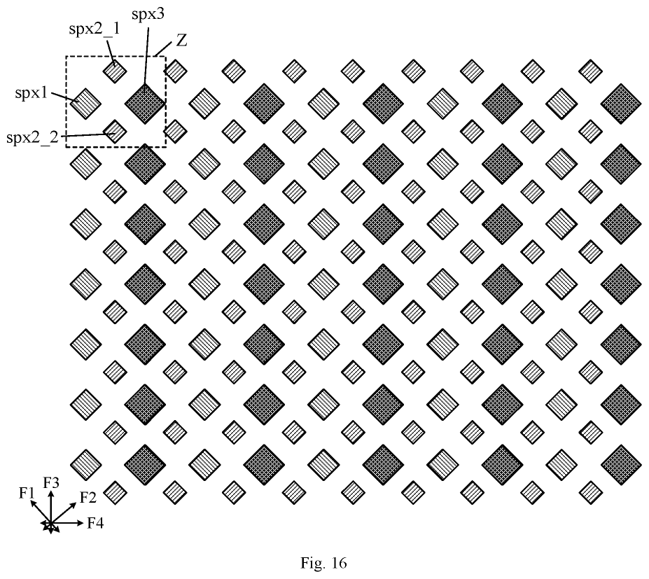

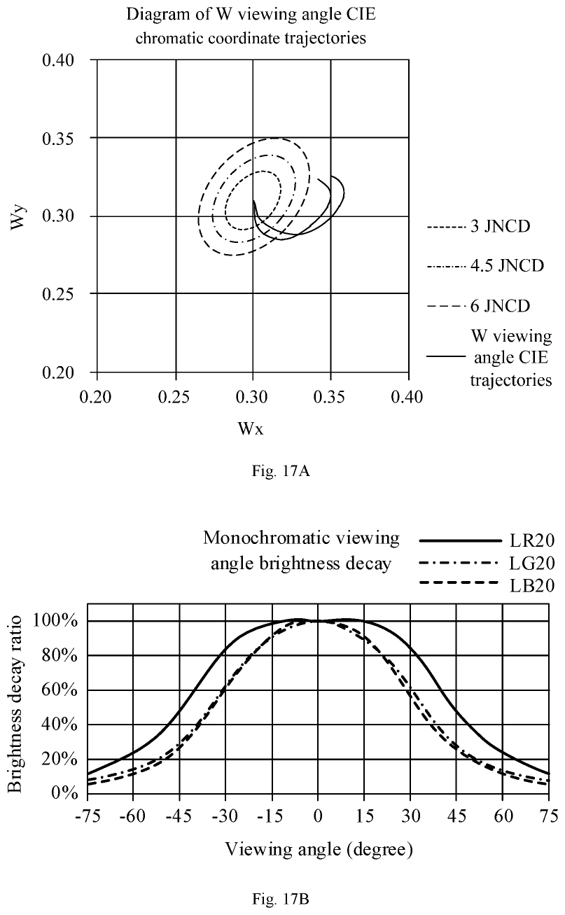

In some embodiments of the present disclosure, as shown in FIG. 15 and FIG. 16, an orthographic projection of the pixel opening of any one pixel in the plurality of pixels on the base substrate 100 is rhombic. For example, orthographic projections of the pixel openings of the first color pixel spx1, the second color pixels spx2_1 and spx2_2 and the third color pixel spx3 on the base substrate 100 are rhombic. Besides, one of the two diagonal lines of the rhombic pixel openings of the first color pixel spx1, the second color pixels spx2_1 and spx2_2 and the third color pixel spx3 is parallel to one of the third direction F3 and the fourth direction F4. For example, the diagonal line formed by the rhombic pixel openings of the first color pixel spx1 and the third color pixel spx3 is parallel to the fourth direction F4, the diagonal line formed by the rhombic pixel openings of the second color pixels spx2_1 and spx2_2 is parallel to the third direction F3, a set of opposite sides arranged oppositely of the rhombic pixel openings of the first color pixel spx1, the second color pixels spx2 and the third color pixel spx3 are parallel to the first direction F1, and the other set of opposite sides arranged oppositely are parallel to the second direction F2. The first direction F1 is perpendicular to the second direction F2, a difference between the first direction F1 and the third direction F3 is in a range of 40° ˜50°, and an angle difference between the second direction F2 and the fourth direction F4 is in a range of 40° ˜50°. For example, an angle difference between the first direction F1 and the third direction F3 is 45°, and an angle difference between the second direction F2 and the fourth direction F4 is 45°.

It needs to be noted that the embodiment is described only by taking the orthographic projections of the pixel openings of the first color pixel, the second color pixels and the third color pixel on the base substrate being rhombic as an example. The present disclosure does not limit a shape of the orthographic projections of the pixel openings of the first color pixel, the second color pixels and the third color pixel on the base substrate. For example, the shape of the orthographic projections of the pixel openings of the first color pixel, the second color pixels and the third color pixel on the base substrate may also be a circle, an ellipse, or other regular or irregular polygons. Besides, the shapes of the orthographic projections of the pixel openings of the pixels in different colors on the base substrate may be the same or not (as long as at least part of edges meet the above ratio at the moment).

In some embodiments of the present disclosure, as shown in FIG. 14 and FIG. 15, in the first direction F1, the pixel opening KK1 of one first color pixel spx1 has a first size r31, the pixel opening KK2_1 of one second color pixel spx2_1 has a second size g31_1, and the first size r31 is smaller than the second size g31_1. For example, a ratio of the first size r31 to the second size g31_1 is in a range of 1:1.2˜1:1.6. In other words, r31:g31_1 is in a range of 1:1.2˜1:1.6. Optionally, r31:g31_1 may be 1:1.2, or r31:g31_1 may be 1:1.3, or r31:g31_1 may be 1:1.4, or r31:g31_1 may be 1:1.5, or r31:g31_1 may be 1:1.6. In actual application, a specific numerical value of r31:g31_1 may be determined according to demands of the actual application, which is not limited here.

In some embodiments of the present disclosure, as shown in FIG. 14 and FIG. 15, in the first direction F1, the pixel opening KK1 of one first color pixel spx1 has the first size r31, the pixel opening KK2_2 of the other second color pixel spx2_2 has a second size g31_2, and the first size r31 is smaller than the second size g31_2. For example, a ratio of the first size r31 to the second size g31_2 is in a range of 1:1.2˜1:1.6. In other words, r31:g31_2 is in a range of 1:1.2˜1:1.6. Optionally, r31:g31_2 may be 1:1.2, or r31:g31_2 may be 1:1.3, or r31:g31_2 may be 1:1.4, or r31:g31_2 may be 1:1.5, or r31:g31_2 may be 1:1.6. In actual application, a specific numerical value of r31:g31_2 may be determined according to demands of the actual application, which is not limited here.

For example, the second sizes g31_1 and g31_2 may be the same, so that the second sizes of the second color pixels spx2_1 and spx2_2 may be designed uniformly, and design uniformity of the display panel is improved.

In some embodiments of the present disclosure, as shown in FIG. 14 and FIG. 15, in the second direction F2, the pixel opening KK1 of one first color pixel spx1 has a third size r32, the pixel opening KK2_1 of one second color pixel spx2_1 has a fourth size g32_1, and the third size r32 is smaller than the fourth size g32_1. For example, a ratio of the third size r32 to the fourth size g32_1 is in a range of 1:1.2˜1:1.6. In other words, r32:g32_1 is in a range of 1:1.2˜1:1.6. Optionally; r32:g32_1 may be 1:1.2, or r32:g32_1 may be 1:1.3, or r32:g32_1 may be 1:1.4, or r32:g32_1 may be 1:1.5, or r32:g32_1 may be 1:1.6. In actual application, a specific numerical value of r32:g32_1 may be determined according to demands of the actual application, which is not limited here.

In some embodiments of the present disclosure, as shown in FIG. 14 and FIG. 15, in the second direction F2, the pixel opening KK1 of one first color pixel spx1 has the third size r32, the pixel opening KK2_2 of the other second color pixel spx2_2 has a fourth size g32_2, and the third size r32 is smaller than the fourth size g32_2. For example, a ratio of the third size r32 to the fourth size g32_2 is in a range of 1:1.2˜1:1.6. In other words, r32:g32_2 is in a range of 1:1.2˜1:1.6. Optionally, r32:g32_2 may be 1:1.2, or r32:g32_2 may be 1:1.3, r32:g32_2 may be 1:1.4, or r32:g32_2 may be 1:1.5, or r32:g32_2 may be 1:1.6. In actual application, a specific numerical value of r32:g32_2 may be determined according to demands of the actual application, which is not limited here.

For example, the fourth sizes g32_1 and g32_2 may be the same, so that the fourth sizes of the second color pixels spx2_1 and spx2_2 may be designed uniformly, and design uniformity of the display panel is improved.

In some embodiments of the present disclosure, as shown in FIG. 14 and FIG. 15, an area of the pixel opening KK2_1 of one second color pixel spx2_1 is smaller than an area of the pixel opening KK3 of one third color pixel spx3. In some examples, in the first direction F1, the pixel opening KK3 of one third color pixel spx3 has a fifth size b31. The fifth size b31 is greater than the second size g31_1. For example, r31:g31_1:b31 is in a range of 1:1.2:1.7˜1:1.6:1.9. Optionally, r31:g31_1:b31 is one of 1:1.2:1.7, 1:1.2:1.8, 1:1.2:1.9, 1:1.3:1.7, 1:1.3:1.8, 1:1.6:1.7, 1:1.6:1.8 or 1:1.6:1.9. In actual application, a specific numerical value of r31:g31_1:b31 may be determined according to demands of the actual application, which is not limited here.

In some embodiments of the present disclosure, as shown in FIG. 14 and FIG. 15, an area of the pixel opening KK2_2 of the other second color pixel spx2_2 is smaller than the area of the pixel opening KK3 of one third color pixel spx3. In some examples, in the first direction F1, the pixel opening KK3 of one third color pixel spx3 has the fifth size b31. The fifth size b31 is greater than the second size g31_2. For example, r31:g31_2:b31 is in a range of 1:1.2:1.7˜1:1.6:1.9. Optionally, r31:g31_2:b31 is one of 1:1.2:1.7, 1:1.2:1.8, 1:1.2:1.9, 1:1.3:1.7, 1:1.3:1.8, 1:1.6:1.7, 1:1.6:1.8 or 1:1.6:1.9. In actual application, a specific numerical value of r31:g31_2:b31 may be determined according to demands of the actual application, which is not limited here.

In some embodiments of the present disclosure, as shown in FIG. 14 and FIG. 15, in the second direction F2, the pixel opening KK3 of one third color pixel spx3 has a sixth size b32. The sixth size b32 is greater than the fourth size g32_1. For example, r32:g32_1:b32 is in a range of 1:1.2:1.7˜1:1.6:1.9. Optionally, r32:g32_1:b32 is one of 1:1.2:1.7, 1:1.2:1.8, 1:1.2:1.9, 1:1.3:1.7, 1:1.3:1.8, 1:1.6:1.7, 1:1.6:1.8 or 1:1.6:1.9. In actual application, a specific numerical value of r32:g32_1:b32 may be determined according to demands of the actual application, which is not limited here.

In some embodiments of the present disclosure, as shown in FIG. 14 and FIG. 15, in the second direction F2, the pixel opening KK3 of one third color pixel spx3 has the sixth size b32. The sixth size b32 is greater than the fourth size g32_2. For example, r32:g32_2:b32 is in a range of 1:1.2:1.7˜1:1.6:1.9. Optionally, r32:g32_2:b32 is one of 1:1.2:1.7, 1:1.2:1.8, 1:1.2:1.9, 1:1.3:1.7, 1:1.3:1.8, 1:1.6:1.7, 1:1.6:1.8 or 1:1.6:1.9. In actual application, a specific numerical value of r32:g32_2:b32 may be determined according to demands of the actual application, which is not limited here.

For example, as shown in FIG. 14, the adjusting structure of the first refractive index layer 150 may include the groove AX, the side walls of the groove AX are in a slope shape, and the second refractive index layer 160 fills the groove AX. The groove AX corresponds to the first color pixel spx1, and the orthographic projection of the bottom end of the pixel opening KK1 of the first color pixel spx1 on the base substrate 100 covers an orthographic projection of a bottom end of the groove AX on the base substrate 100. For example, a section of each groove AX is an inverted trapezoid, the bottom end of the groove AX is a short edge of the inverted trapezoid, and a top end of the groove AX is a long edge of the inverted trapezoid. The section of each groove AX is the inverted trapezoid, the side wall of the groove AX is in the slope shape, and the refractive index of the second refractive index layer 160 is greater than the refractive index of the first refractive index layer 150, by designing a specific numerical value of an inclination angle β of the side wall of the groove AX, a total reflection plane may be formed on the side wall of the groove AX, and when light L11 emitted from an edge (such as a right side edge) of the pixel opening of the first color pixel spx1 is incident on a side wall position SI on a left side of the groove AX, total reflection may occur. Likewise, when light emitted from a left side edge of the pixel opening of the first color pixel spx1 is incident on a side wall position on a right side of the groove AX, total reflection may occur as well. Besides, when light emitted from a middle region of the pixel opening of the first color pixel spx1 is incident on the side wall positions on the left side and right side of each groove AX, total reflection does not occur, and the light may be refracted out. Accordingly, a part of light rays emitted from the pixel openings of the first color pixels spx1 may be emitted to the outside of the display panel so as to implement light emitting, moreover, the other part of light rays emitted from the pixel openings of the first color pixels spx1 are absorbed by the black matrix 130, the brightness decay rate of the light beams emitted from the pixel openings of the first color pixels spx1 at the large viewing angle may be increased, the viewing angle brightness decay rate of the light rays emitted from the pixel openings of the first color pixel spx1 and the viewing angle brightness decay rate of the light rays emitted from the pixel openings of the second color pixels spx2 may keep consistent as much as possible, and thus color cast of the display panel may be reduced.

It needs to be noted that an implementation of the grooves AX in the embodiment may refer to the above implementation and is omitted here.

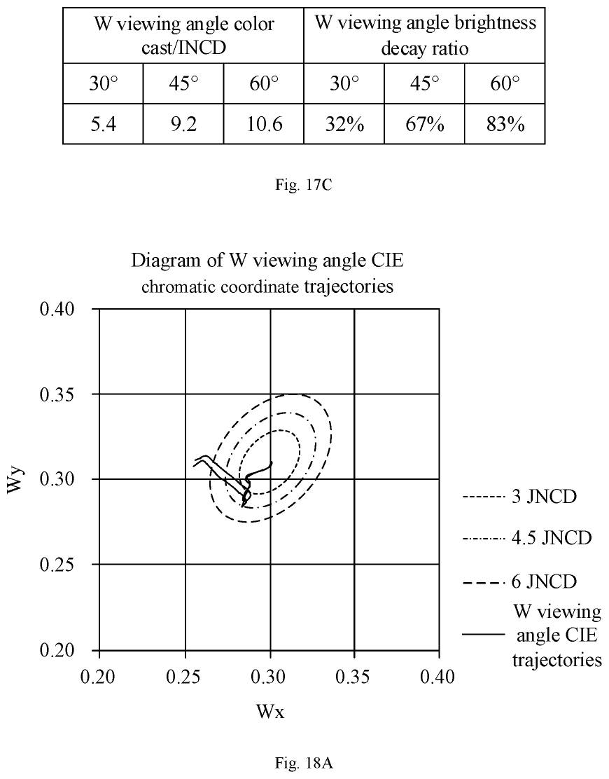

As shown in FIG. 17A to FIG. 17B. FIG. 17A is a diagram of W viewing angle CIE (Commission Internationale d′Eclairage) chromatic coordinate trajectories when an OLED display panel generates white light by mixing of three-primary-color light of red, green and blue in the related art. FIG. 17B is a diagram of monochromatic viewing angle brightness decays of a red OLED (such as R), a green OLED (such as G) and a blue OLED (such as B) in the related art. FIG. 17C is a schematic diagram of contrasts of specific parameters of W viewing angle color cast and W viewing angle brightness decay ratios when an OLED display panel generates white light by mixing of three-primary-color light of red, green and blue in the related art. It can be seen from FIG. 17A to FIG. 17B that brightness decay rates of OLEDs in different colors at different viewing angles are inconsistent, wherein the brightness decay of the red OLED is slow, the brightness decay of the green OLED is fast, and when RGB are mixed to generate the white light, the phenomenon of color cast occurs at the different viewing angles when the display panel performs image display.

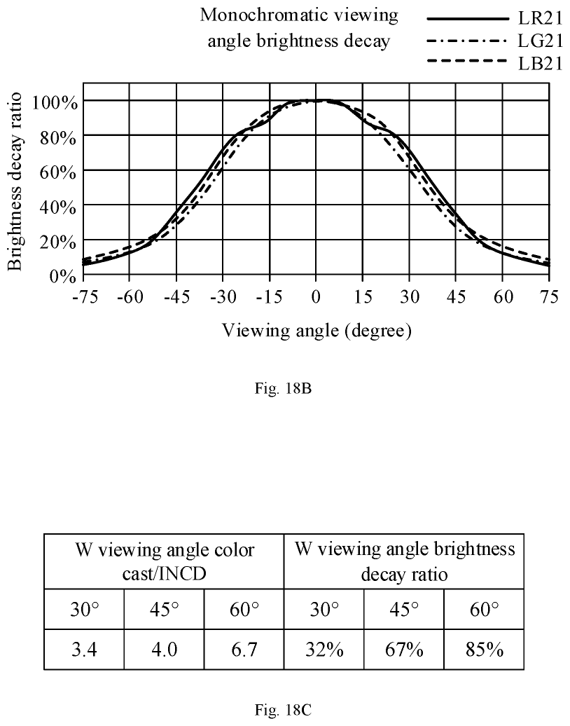

As shown in FIG. 18A to FIG. 18B. FIG. 18A is a diagram of W viewing angle CIE (Commission Internationale d′Eclairage) chromatic coordinate trajectories when a display panel shown in FIG. 14 generates white light by mixing of three-primary-color light of red, green and blue. FIG. 18B is a diagram of monochromatic viewing angle brightness decays of a display panel shown in FIG. 14. FIG. 18C is a schematic diagram of contrasts of specific parameters of W viewing angle color cast and W viewing angle brightness decay ratios when a display panel shown in FIG. 14 generates white light by mixing of three-primary-color light of red, green and blue. In FIG. 18B. LR21 represents a curve of a monochromatic viewing angle brightness decay of a red pixel. LG21 represents a curve of a monochromatic viewing angle brightness decay of a green pixel, and LB21 represents a curve of a monochromatic viewing angle brightness decay of a blue pixel. It can be seen from FIG. 18A to FIG. 18B that by using the display panel provided by the embodiment of the present disclosure, brightness decay rates of OLEDs in different colors at the different viewing angles tend to be consistent, and when RGB are mixed to generate the white light, color cast generated at the different viewing angles when the display panel performs image display is relieved.

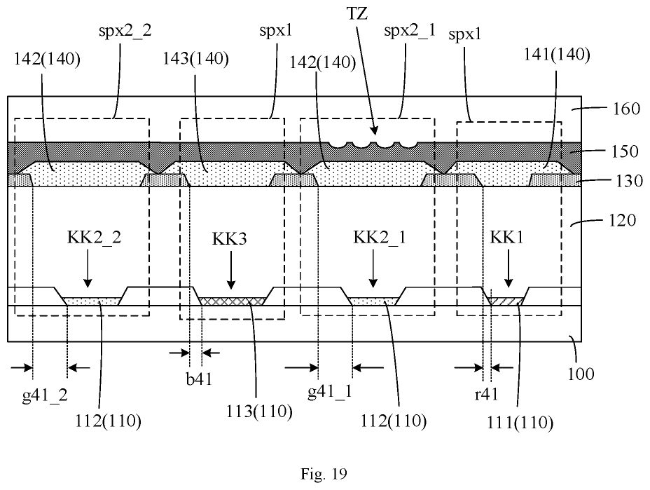

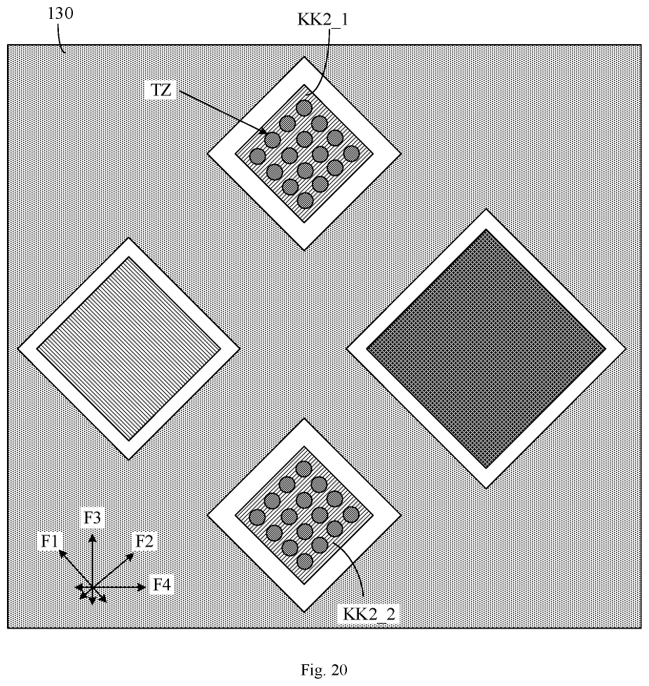

An embodiment of the present disclosure provides a schematic structural diagram of yet some other display panels, as shown in FIG. 19. A transformation is made specific to the implementation in the above embodiment. Only a difference between the embodiment and the above embodiment is described below; and the same parts between them are omitted here.

In some embodiments of the present disclosure, as shown in FIG. 19 and FIG. 20, the adjusting structure of the first refractive index layer 150 may also include concave lens array TZ, and the second refractive index layer 160 fills the concave lens array TZ. The concave lens array TZ corresponds to the second color pixels spx2_1 and spx2_2. In other words, each concave lens array TZ is arranged in the second color pixel spx2_1, and an orthographic projection of a bottom end of the pixel opening KK2_1 of the second color pixel spx2_1 on the base substrate 100 covers an orthographic projection of a region where the concave lens array TZ is located on the base substrate 100. The concave lens array TZ is also arranged in the second color pixel spx2_2, and an orthographic projection of a bottom end of the pixel opening KK2_2 of the second color pixel spx2_2 on the base substrate 100 covers an orthographic projection of a region where the concave lens array TZ is located on the base substrate 100. The refractive index of the second refractive index layer 160 is greater than the refractive index of the first refractive index layer 150, when light emitted from the pixel openings of the second color pixels spx2_1 and spx2_2 is incident on the concave lens arrays TZ, the light enters an optically denser medium from an optically thinner medium, according to a normal of a center of a sphere of each concave lens, a direction of the light rays changes, the brightness decay rate of the light beams emitted from the pixel opening of the second color pixel spx2 at the large viewing angle may be reduced, the viewing angle brightness decay rate of the light rays emitted from the pixel opening of the first color pixel spx1 and the viewing angle brightness decay rate of the light rays emitted from the pixel opening of the second color pixel spx2 keep consistent as much as possible, and thus color cast of the display panel may be reduced.

It needs to be noted that an implementation of the concave lens arrays TZ in the embodiment may refer to the above implementation and is omitted here.

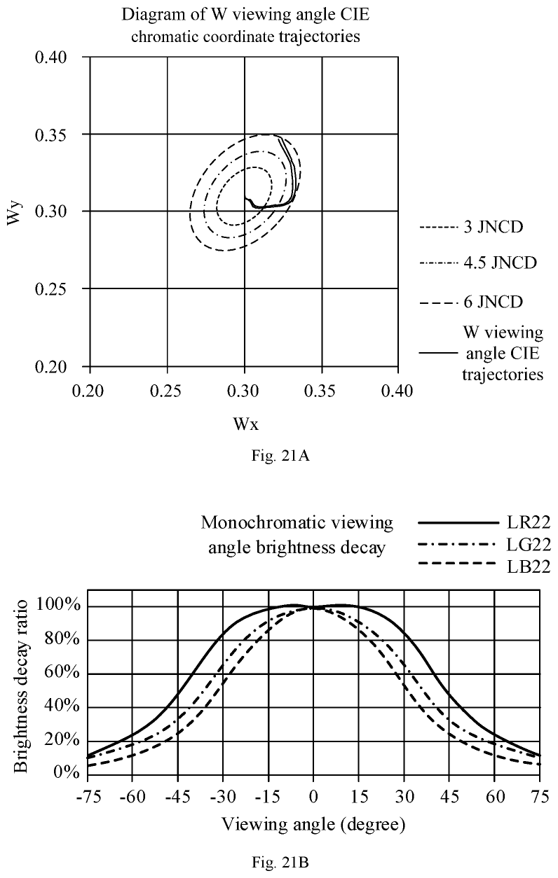

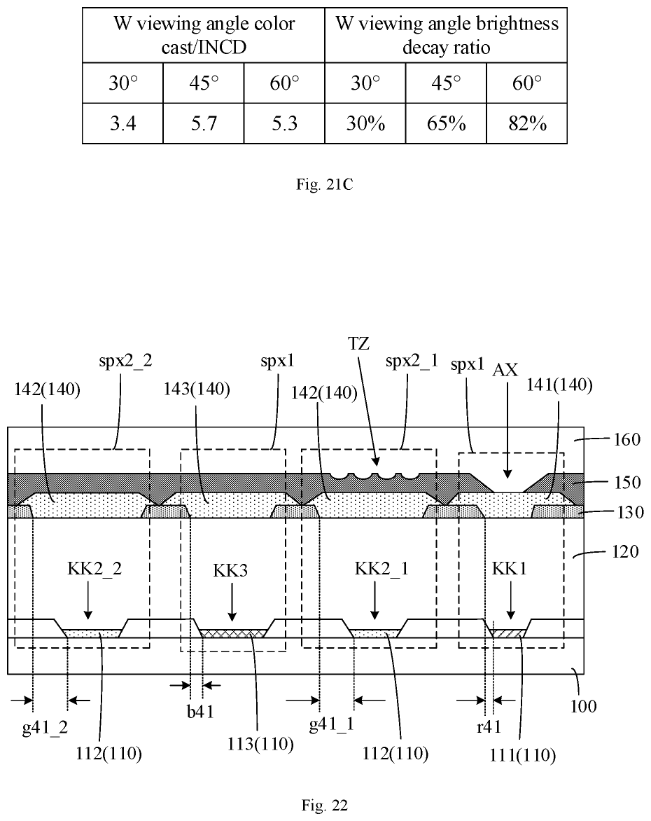

As shown in FIG. 21A to FIG. 21B. FIG. 21A is a diagram of W viewing angle CIE (Commission Internationale d′Eclairage) chromatic coordinate trajectories when a display panel shown in FIG. 19 generates white light by mixing of three-primary-color light of red, green and blue. FIG. 21B is a diagram of monochromatic viewing angle brightness decays of a display panel shown in FIG. 19. FIG. 21C is a schematic diagram of contrasts of specific parameters of W viewing angle color cast and W viewing angle brightness decay ratios when a display panel shown in FIG. 19 generates white light by mixing of three-primary-color light of red, green and blue. In FIG. 21B. LR22 represents a curve of a monochromatic viewing angle brightness decay of a red pixel. LG22 represents a curve of a monochromatic viewing angle brightness decay of a green pixel, and LB22 represents a curve of a monochromatic viewing angle brightness decay of a blue pixel. It can be seen from FIG. 21A to FIG. 21B that by using the display panel provided by the embodiment of the present disclosure, brightness decay rates of OLEDs in different colors at the different viewing angles tend to be consistent, and when RGB are mixed to generate the white light, color cast generated at the different viewing angles when the display panel performs image display is relieved.

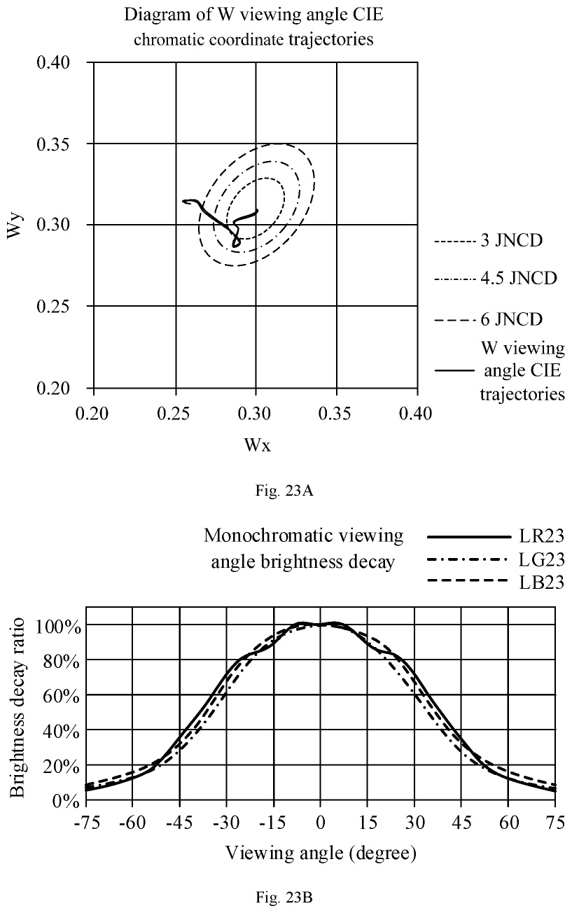

An embodiment of the present disclosure provides a schematic structural diagram of yet some other display panels, as shown in FIG. 22. A transformation is made specific to an implementation in the above embodiment. Only a difference between the embodiment and the above embodiment is described below; and the same parts between them are omitted here.

In some embodiments of the present disclosure, as shown in FIG. 22, the adjusting structure of the first refractive index layer 150 may not only include the groove AX, but also include the concave lens array TZ. The groove AX corresponds to the first color pixel spx1, and the concave lens array TZ corresponds to the second color pixel spx2_1 and spx2_2. It needs to be noted that implementations of the groove AX and the concave lens array TZ may refer to the above implementations and are omitted here.

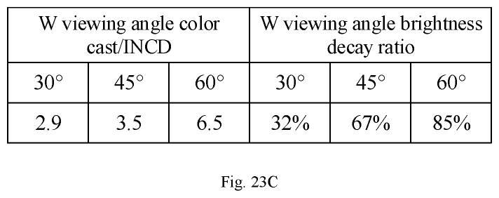

As shown in FIG. 23A to FIG. 23B. FIG. 23A is a diagram of W viewing angle CIE (Commission Internationale d′Eclairage) chromatic coordinate trajectories when a display panel shown in FIG. 22 generates white light by mixing of three-primary-color light of red, green and blue. FIG. 23B is a diagram of monochromatic viewing angle brightness decays of a display panel shown in FIG. 22. FIG. 23C is a schematic diagram of contrasts of specific parameters of W viewing angle color cast and W viewing angle brightness decay ratios when a display panel shown in FIG. 22 generates white light by mixing of three-primary-color light of red, green and blue. In FIG. 23B. LR23 represents a curve of a monochromatic viewing angle brightness decay of a red pixel, LG23 represents a curve of a monochromatic viewing angle brightness decay of a green pixel, and LB23 represents a curve of a monochromatic viewing angle brightness decay of a blue pixel. It can be seen from FIG. 23A to FIG. 23B that by using the display panel provided by the embodiment of the present disclosure, brightness decay rates of OLEDs in different colors at the different viewing angles tend to be consistent, and when RGB are mixed to generate the white light, color cast generated at the different viewing angles when the display panel performs image display is relieved.

An embodiment of the present disclosure further provides a display apparatus, including the above display apparatus provided by the embodiment of the present disclosure. A principle of solving problems of the display apparatus is similar to that of the above display panel, so implementation of the display apparatus may refer to implementation of the above display panel, and repetitions are omitted here.

During specific implementation, in the embodiment of the present disclosure, the display apparatus may be: a mobile phone, a tablet computer, a television, a display, a notebook computer, a digital photo frame, a navigator and any product or component with a display function. Other necessary components of the display apparatus should be understood by those ordinarily skilled in the art and are neither described in detail here, nor supposed to be used as a limitation to the present disclosure.

Though preferred embodiments of the present disclosure have been described, those skilled in the art can make extra changes and modifications to these embodiments once they know a basic inventive concept. Therefore, the appended claims intend to be construed as including the preferred embodiments and all changes and modifications falling within the scope of the present disclosure.

Apparently, those skilled in the art can make various modifications and transformations to the embodiments of the present disclosure without departing from the spirit and scope of the embodiments of the present disclosure. In this case, if these modifications and transformations of the embodiments of the present disclosure fall within the scope of the claims of the present disclosure and their equivalents, the present disclosure also intends to contain these modifications and transformations.

1. A display panel, comprising:
a base substrate, comprising a plurality of pixels; and
a pixel defining layer, located on the base substrate and provided with a plurality of pixel openings, wherein the plurality of pixels are in one-to-one correspondence with the plurality of pixel openings; wherein
the plurality of pixels comprise first color pixels and second color pixels; a decay rate of viewing angle brightness of pixel openings of the first color pixels in unit area is a first decay rate, a decay rate of viewing angle brightness of pixel openings of the second color pixels in unit area is a second decay rate, and the first decay rate is smaller than the second decay rate; and
an area of the pixel opening of one of the first color pixels is smaller than an area of the pixel opening of one of the second color pixels.

2. The display panel according to claim 1, wherein in a first direction, the pixel opening of one of the first color pixels is provided with a first size, the pixel opening of one of the second color pixels is provided with a second size, and the first size is smaller than the second size.

3. The display panel according to claim 2, wherein a ratio of the first size to the second size is in a range of 1:1.2 to 1:1.6.

4. The display panel according to claim 1, wherein in a second direction, the pixel opening of one of the first color pixels is provided with a third size, the pixel opening of one of the second color pixels is provided with a fourth size, the third size is smaller than the fourth size, and the second direction intersects with the first direction.

5. The display panel according to claim 4, wherein a ratio of the third size to the fourth size is in a range of 1:1.2 to 1:1.6.

6. The display panel according to claim 1, wherein the plurality of pixels further comprise third color pixels; and
the area of the pixel opening of one of the second color pixels is smaller than an area of a pixel opening of one of the third color pixels.

7. The display panel according to claim 1, further comprising:
a black matrix, located on a side of the pixel defining layer facing away from the base substrate, wherein the black matrix is provided with a plurality of black matrix openings; the plurality of black matrix openings are in one-to-one correspondence with the plurality of pixel openings; and
orthographic projections of bottom ends of the black matrix openings on the base substrate cover orthographic projections of bottom ends of the pixel openings on the base substrate.

8. The display panel according to claim 7, wherein in the first color pixel, first opening spacing is between an edge of an orthographic projection of a bottom end of a black matrix opening on the base substrate and an edge of the orthographic projection of the bottom end of the pixel opening on the base substrate;
in the second color pixel, second opening spacing is between an edge of an orthographic projection of a bottom end of a black matrix opening on the base substrate and an edge of the orthographic projection of the bottom end of the pixel opening on the base substrate; and
the first opening spacing is smaller than the second opening spacing.

9. The display panel according to claim 8, wherein a ratio of the first opening spacing to the second opening spacing is in a range of 1:1.2 to 1:2.2.

10. The display panel according to claim 8, wherein the plurality of pixels further comprise the third color pixels, and in each of the third color pixels, third opening spacing is between an edge of an orthographic projection of a bottom end of a black matrix opening on the base substrate and an edge of the orthographic projection of the bottom end of the pixel opening on the base substrate; and
the third opening spacing is not smaller than the first opening spacing and is smaller than the second opening spacing.

11. The display panel according to claim 1, further comprising:
a first refractive index layer, located on the side of the pixel defining layer facing away from the base substrate; and
a second refractive index layer, located on a side of the first refractive index layer facing away from the base substrate; wherein
a refractive index of the first refractive index layer is smaller than a refractive index of the second refractive index layer;
the first refractive index layer is provided with adjusting structures, and each of the adjusting structures corresponds to at least one of the first color pixel and the second color pixel; and
the adjusting structure is configured to reduce an emergent angle of light rays emitted from the pixel opening of the corresponding pixel.

12. The display panel according to claim 11, wherein the adjusting structure comprises a groove, side walls of the groove are in a slope shape, and the second refractive index layer fills the groove; and
the groove corresponds to the first color pixel, and an orthographic projection of a bottom end of the pixel opening of the first color pixel on the base substrate covers an orthographic projection of a bottom end of the groove on the base substrate.

13. The display panel according to claim 12, wherein a first indentation value is between an edge of the orthographic projection of the bottom end of the pixel opening of the first color pixel on the base substrate and an edge of the orthographic projection of the bottom end of the groove on the base substrate, and the first indentation value is not smaller than zero and not larger than 2 μm.

14. The display panel according to claim 12, wherein an orthographic projection of a top end of the pixel opening of the first color pixel on the base substrate covers an orthographic projection of a top end of the groove on the base substrate; or an orthographic projection of a top end of the pixel opening of the first color pixel on the base substrate is located within an orthographic projection of a top end of the groove on the base substrate.

15. The display panel according to claim 11, wherein the adjusting structure comprises a concave lens array; the second refractive index layer fills the concave lens array; and
the concave lens array corresponds to the second color pixel, and an orthographic projection of a bottom end of the pixel opening of the second color pixel on the base substrate covers an orthographic projection of a region where the concave lens array is located on the base substrate.

16. The display panel according to claim 15, wherein in the concave lens array, sizes of concave lenses are the same, and spacing distances between every two adjacent concave lenses are the same.

17. The display panel according to claim 1, wherein the plurality of pixels further comprise the third color pixels; one of the first color pixels, one of the second color pixels and one of the third color pixels constitute a repeating unit; in the repeating unit, the first color pixel and the second color pixel are arranged in the first direction, and a straight line passing through a center of the pixel opening of the third color pixel and perpendicular to the first direction is located at a gap between the pixel opening of the first color pixel and the pixel opening of the second color pixel; and a plurality of repeating units are arranged in sequence in the first direction and constitute pixel rows.

18. The display panel according to claim 1, wherein the plurality of pixels further comprise the third color pixels;
one first color pixel, two second color pixels and one third color pixel constitute a repeating unit; in the repeating unit, centers of the pixel openings of the first color pixel, the two second color pixels and the third color pixel constitute a quadrangle, a connecting line of the center of the pixel opening of the first color pixel and the center of the pixel opening of the third color pixel constitutes a first diagonal line of the quadrangle, and a plurality of repeating units are arranged in sequence in a direction parallel to the first diagonal line and constitute pixel rows.

19. (canceled)

20. The display panel according to claim 1, wherein an orthographic projection of the pixel opening of any one pixel in the plurality of pixels on the base substrate is in a shape of at least one of rectangle, rhombus or circle.

21. A display apparatus, comprising the display panel according to claim 1.
